(19) United States
(12) Patent Application Publication
(10) Pub. No.: US 2026/0304983 A1
(43) Pub. Date: Oct. 1, 2026

(54) SEMICONDUCTOR DEVICE AND METHODS OF FORMATION

(71) Applicant: Taiwan Semiconductor Manufacturing Company, Ltd., Hsinchu (TW)

(72) Inventors: Ming-Hsien YANG, Taichung City (TW); Bo-Ruei CHEN, Changhua County (TW); Chun-Hao CHOU, Tainan City (TW); Kuo-Cheng LEE, Tainan City (TW); Ping-Hao LIN, Tainan City (TW)

(21) Appl. No.: 19/093,956

(22) Filed: Mar. 28, 2025

(51) Int. Cl. H10F 39/00; H10F 39/18

(52) U.S. Cl. CPC H10F 39/806; H10F 39/014; H10F 39/18; H10F 39/807

(57) ABSTRACT

A dynamic vision sensor (DVS) device uses a nano-prism structure to direct and focus light toward photodiodes of pixel sensors of the DVS device. Building on some of the principles for the operation of nano-light pillars, the nano-prism structure is arranged to control the speed and deflection angles of incident light traveling through different portions of the nano-prism structure. For example, the resulting direction and focal points of incident light may be easily modified by changing the location, dimensions, and/or materials of portions of the nano-prism structure. The nano-prism structure may be implemented without micro-lenses to focus light to non-filter (e.g., non-red-green-blue) pixel sensors to encode per-pixel luminance changes to form digital images. As a result, DVS devices implementing the nano-prism structure may occupy less area, are more amenable to design changes, and have a lower susceptibility to light loss (e.g., higher quantum efficiency) than DVS devices using micro-lenses.

### BACKGROUND

Complementary metal oxide semiconductor (CMOS) image sensors utilize light-sensitive CMOS circuitry to convert light energy (e.g., photons) into electrical energy. The light-sensitive CMOS circuitry may include a photodiode formed in a silicon substrate. As the photodiode is exposed to light, an electrical charge is induced in the photodiode (referred to as a photocurrent). The photodiode may be coupled to a transfer gate, which is used to sample the charge of the photodiode. Colors may be determined by placing filters over the light-sensitive CMOS circuitry.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1 is a diagram of an example of a portion of an image sensor device described herein.

FIGS. 2A-2E are diagrams of example implementations of a portion of a pixel sensor array described herein.

FIGS. 3A-3J are diagrams of an example implementation of forming an image sensor device described herein.

FIGS. 4A-4D are diagrams of an example implementation of forming an image sensor device described herein.

FIGS. 5A and 5B are diagrams of an example implementation of forming an image sensor device described herein.

FIGS. 6A-6D are diagrams of an example implementation of forming an image sensor device described herein.

FIGS. 7A-7E are diagrams of example implementations of a portion of a pixel sensor array described herein.

FIGS. 8A-8F are diagrams of example implementations of a portion of a pixel sensor array described herein.

FIG. 9 is a flowchart of an example process associated with forming an image sensor device described herein.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

Complementary metal oxide semiconductor (CMOS) image sensor devices have a broad spectrum of use cases, including digital cameras, security cameras, night vision, and/or automotive sensing, among other examples. CMOS image sensor devices may use micro-lenses to focus incident light toward the photodiodes of pixel sensors of the CMOS image sensor devices. In some use cases, a CMOS image sensor device can be exposed to changing environments that have different levels of illuminance. For example, in an automotive sensing use case, a CMOS image sensor device may experience constantly changing levels of illuminance as an automobile in which the CMOS image sensor device is included moves between environments having different levels of illuminance. This can occur, for example, where the automobile transitions between a tunnel and an open environment or where the automobile passes under a bridge, among other examples.

A dynamic vision sensor (DVS) asynchronously captures visual information in a manner similar to the human eye, responding to changes in luminance (e.g., brightness) and scene, instead of capturing images at a fixed frame rate. Individual pixels may independently produce an output if there is a detected change in luminance. An image may be continuously synthesized to form a temporal stream of events. Some image sensor devices (e.g., cameras) use a color filter array including red, green, and blue (RGB) filters to create a full-color image to form an image. In contrast, a DVS may encode per-pixel luminance changes to form digital images without using a color filter array.

Nano-light pillars (NLPs) are examples of structures that may be used to direct light to specific color pixels. Also, referred to as meta-surfaces, NLPs may reroute light of different wavelengths to effectively increase areas that receive each color of light. This may be useful in low-light conditions. NLPs may include two layers of pillars to gather light from neighboring pillars through refraction.

Some implementations described herein provide a DVS device that uses a nano-prism structure to direct and focus light toward photodiodes of pixel sensors of the DVS device. Building on some of the principles for the operation of NLPs, the nano-prism structure is arranged to control the speed and deflection angles of incident light traveling through different portions of the nano-prism structure. For example, the resulting direction and focal points of incident light may be easily modified by changing the location, dimensions, and/or materials of portions of the nano-prism structure. The nano-prism structure may be implemented without micro-lenses to focus light to non-filter (e.g., non-RGB) pixel sensors to encode per-pixel luminance changes to form digital images. As a result, DVS devices implementing the nano-prism structure may occupy less area, are more amenable to design changes, and have a lower susceptibility to light loss (and therefore higher quantum efficiency) than DVS devices using micro-lenses.

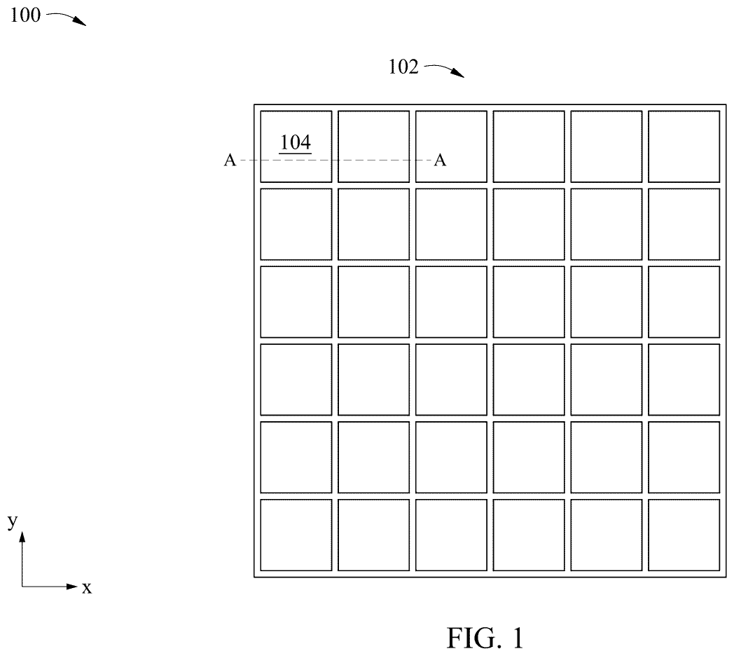

FIG. 1 is a diagram of an example of a portion of an image sensor device 100 (e.g., a DVS device) described herein. The portion of the image sensor device 100 illustrated in FIG. 1 includes a pixel sensor array 102. The pixel sensor array 102 may include a pixel sensor array configured for sensing changes in luminance. FIG. 1 illustrates a top view of the pixel sensor array 102.

As shown in FIG. 1, the pixel sensor array 102 includes a plurality of pixel sensors 104. The pixel sensors 104 may be filterless (e.g., non-RGB or non-filter) pixel sensors, which receive light that has not been filtered (e.g., has not passed through) a color filter such as, for example, a red, green, and/or blue filter. The pixel sensors 104 may be referred to herein as white pixel sensors (or “clear” pixel sensors) 104. The pixel sensors 104 may be arranged in a grid in an x-y plane (e.g., a lateral or horizontal plane) to form the pixel sensor array 102. For example, the pixel sensors 104 may be arranged in a plurality of rows in the x-direction in the image sensor device 100, and may be arranged in a plurality of columns in the y-direction in the image sensor device 100. However, other arrangements for the pixel sensors 104 in the pixel sensor array 102 are within the scope of the present disclosure.

In some implementations, the pixel sensors 104 are square-shaped (as shown in the example in FIG. 1). In some implementations, the pixel sensors 104 include other shapes such as rectangle shapes, circle shapes, octagon shapes, diamond shapes, and/or other shapes.

Each pixel sensor 104 individually generates an output when there is a detected (e.g., measured) change in luminance by a photodiode of the pixel sensor 104. The change in luminance may be with respect to a reference luminance, and an output (e.g., event) may be generated when a difference from the reference luminance exceeds a threshold. A change in the luminance may be an increase or a decrease in the luminance. An image may be continuously synthesized to generate a temporal stream of events based on the outputs of each pixel sensor 104.

As indicated above, FIG. 1 is provided as an example. Other examples may differ from what is described with regard to FIG. 1.

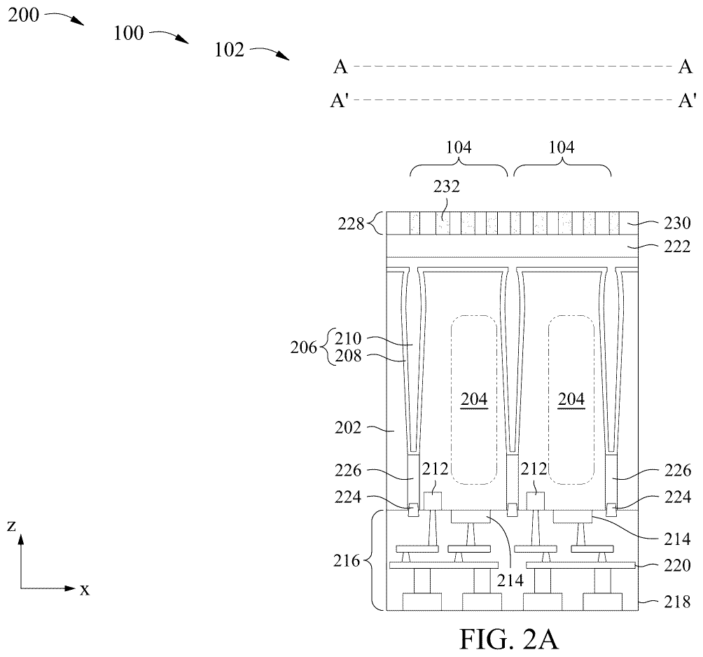

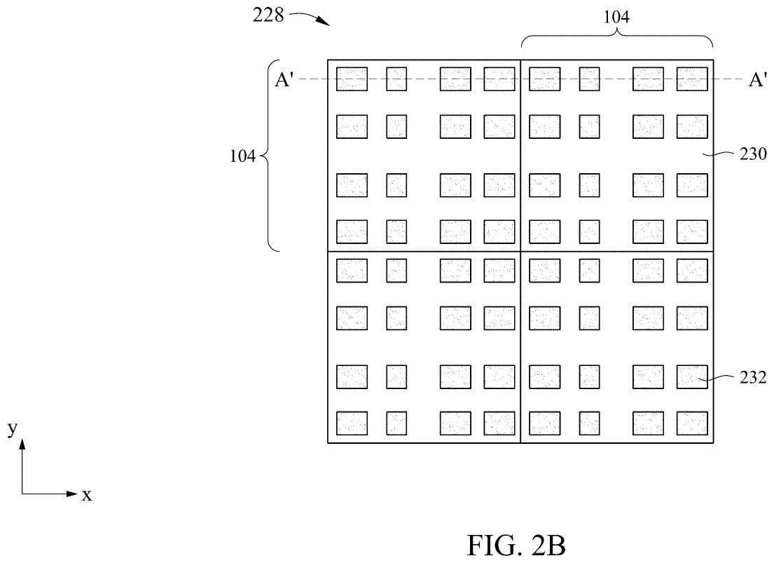

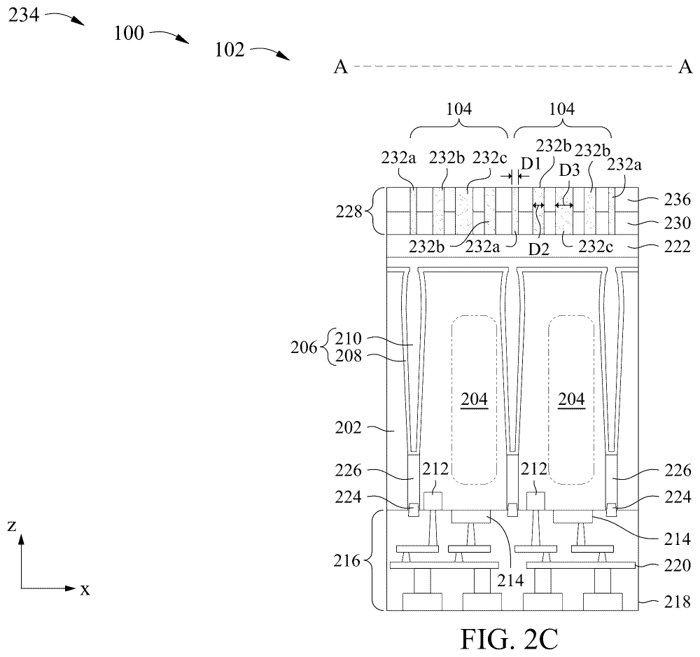

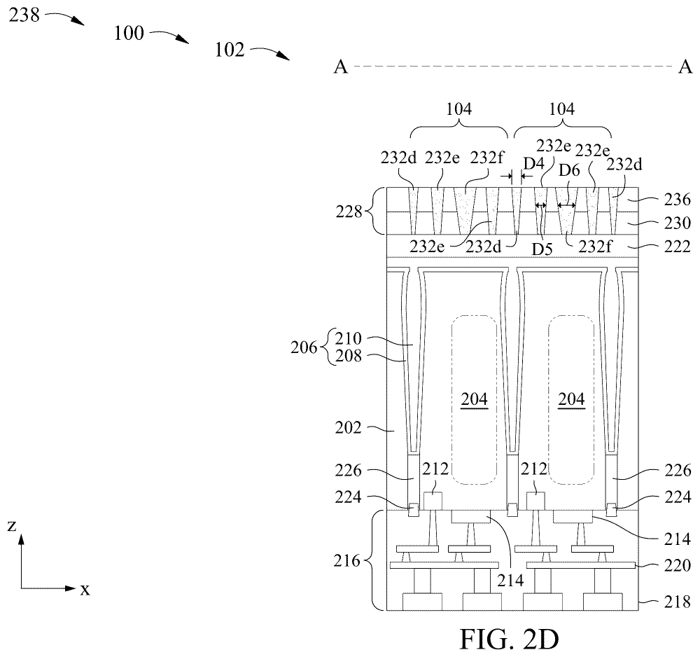

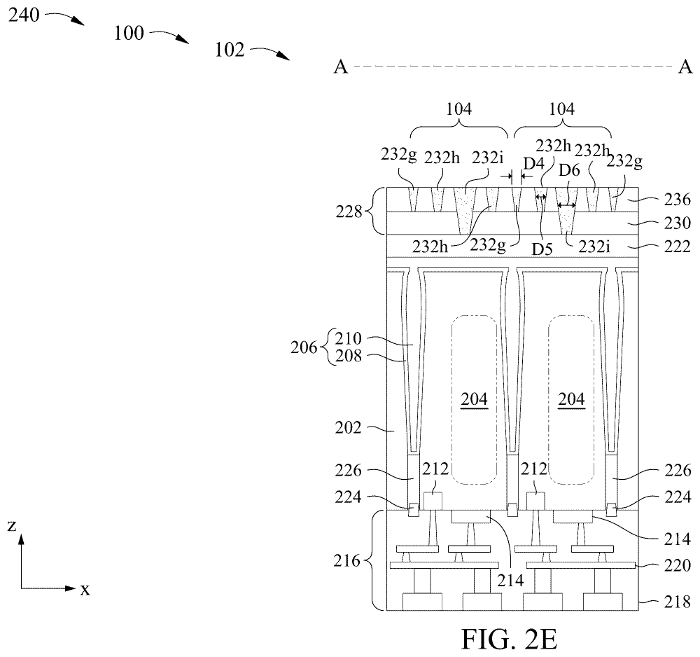

FIGS. 2A-2E are diagrams of example implementations of a portion of a pixel sensor array described herein. For example, FIG. 2B illustrates a top view, and each of FIGS. 2A, and 2C-2E illustrates a cross-sectional view of an example implementation of a portion of the pixel sensor array 102 of the image sensor device 100. However, the example implementations of the portion of the pixel sensor array 102 illustrated in FIGS. 2A-2E may be used in other pixel sensor arrays. The cross-sectional views illustrated in FIGS. 2A and 2C-2E are along the line A-A in FIG. 1. In addition, the cross-sectional view in FIG. 2A is also along the line A′-A′ in FIG. 2B.

The example implementations of the portion of the pixel sensor array 102 of the image sensor device 100 illustrated in FIGS. 2A-2E each include a nano-prism structure. A nano-prism structure may be included above the pixel sensors 104 in the pixel sensor array 102 to control the speed and angles of incident light traveling through different portions of the nano-prism structure so that the light is directed to a focal point where a photodiode may be located. For example, the resulting direction and focal points of incident light may be easily managed by changing the location, dimensions, and/or materials of portions of the nano-prism structure, so that light loss is minimized and/or prevented, thereby increasing the quantum efficiency of each pixel sensor 104.

Turning to FIG. 2A, an example implementation 200 of a portion of the pixel sensor array 102 of the image sensor device 100 includes two adjacent pixel sensors 104. As shown in FIG. 2A, the image sensor device 100 may include a substrate 202. The substrate 202 may include a semiconductor layer, a semiconductor die substrate, a semiconductor wafer, a stacked semiconductor wafer, or another type of substrate in which semiconductor pixels may be formed. In some implementations, the substrate 202 is formed of silicon (Si) (e.g., a silicon substrate), a material including silicon, a III-V compound semiconductor material such as gallium arsenide (GaAs), a silicon on insulator (SOI), or another type of semiconductor material that is capable of generating a charge from photons of incident light. In some implementations, the substrate 202 is formed of a doped material (e.g., a p-doped material or an n-doped material), such as a doped silicon.

Each pixel sensor 104 may include a photodiode 204 that is included in the substrate 202. The photodiodes 204 may include a plurality of regions of the substrate 202 that are doped with various types of ions to form a p-n junction or a PIN junction (e.g., a junction between a p-type portion, an intrinsic (or undoped) type portion, and an n-type portion). For example, the substrate 202 may be doped with an n-type dopant to form one or more n-type regions of a photodiode 204, and the substrate 202 may be doped with a p-type dopant to form a p-type region of the photodiode 204. A photodiode 204 may be configured to absorb photons of incident light that enter the substrate 202. The absorption of photons causes the photodiode 204 to accumulate a charge (referred to as a photocurrent) due to the photoelectric effect. Photons may bombard the photodiode 204, which causes emission of electrons in the photodiode 204.

An isolation structure 206 may be included around the photodiodes 204 of the pixel sensors 104 of the pixel sensor array 102. The isolation structure 206 may be a deep trench isolation (DTI) structure that includes a plurality of interconnected elongated trenches that extend downward into the substrate 202. The elongated trenches may extend into the substrate 202 from a backside surface of the substrate 202 opposing the frontside surface. The pixel sensor array 102 may be referred to as a backside illuminated (BSI) pixel sensor array in that photons enter the photodiodes 204 from the backside surface of the substrate 202. Thus, the isolation structure 206 may be referred to as a backside DTI (BDTI) structure. Alternatively, the isolation structure 206 may include a frontside DTI (FDTI) structure that extends into the substrate from the front surface of the substrate 202.

The isolation structure 206 may include one or more layers. The one or more layers may include a liner 208 and a fill layer 210, among other examples. A portion of the liner 208 and/or a portion of the fill layer 210 may extend along the backside surface of the substrate 202. Alternatively, the liner 208 and/or the fill layer 210 may be omitted from the backside surface of the substrate 202.

The fill layer 210 may confine incident light around a photodiode 204 of an associated pixel sensor 104 to increase the quantum efficiency of the pixel sensor and/or to reduce optical crosstalk between adjacent pixel sensors 104 in the pixel sensor array 102. In some implementations, the fill layer 210 includes one or more dielectric materials, such as a silicon oxide (SiOₓ), a silicon nitride (SiₓN_{y}), a silicon carbide (SiCₓ), a silicon carbon nitride (SiCN), and/or a silicon oxynitride (SiON), among other examples. The liner 208 may include a silicon nitride (SiₓN_{y}), a silicon carbide (SiCₓ), an aluminum oxide (AlₓO_{y} such as Al₂O₃), a tantalum oxide (TaₓO_{y} such as Ta₂O₅), a hafnium oxide (HfOₓ such as HfO₂) and/or another high dielectric constant (high-k) dielectric material.

The photocurrent generated by a photodiode 204 may be transferred and/or stored in an associated floating diffusion (FD) node 212 in the substrate 202. An FD node 212 may include a doped portion (e.g., an n-doped portion, a p-doped portion) of the substrate 202 that is configured to accumulate and store a photocurrent.

Each of the pixel sensors 104 may include a transfer gate 214. A transfer gate 214 may be located at a frontside surface of the substrate 202. A transfer gate 214 may be configured to transfer the photocurrent generated by a photodiode 204 to an FD node 212. For example, the transfer gate 214 of a pixel sensor 104 may be configured to transfer the photocurrent generated by the photodiode 204 of the pixel sensor 104 to the FD node 212 of the pixel sensor 104. A transfer gate 214 may be implemented by a field effect transistor (FET), such as a planar FET, a finFET, a nanostructure FET (e.g., a gate all around (GAA) FET, a nanowire FET, a nanosheet FET, a multi-bridge channel FET, a nanoribbon FET), and/or another type of FET.

An interconnect layer 216 (e.g., a back end of line (BEOL) region or backend region) may be included on the frontside of the substrate 202. The interconnect layer 216 may include one or more dielectric layers 218 and one or more metallization layers 220 included in the one or more dielectric layers 218. One or more of the metallization layers 220 may be electrically connected with portions of the pixel sensor array 102, including the FD nodes 212 and/or the transfer gates 214. The one or more dielectric layers 218 may include a silicon oxide (SiOₓ), a silicon nitride (SiₓN_{y}), a silicon carbide (SiCₓ), or a mixture thereof, such as a silicon carbon nitride (SiCN), or a silicon oxynitride (SiON), among other examples. The one or more metallization layers 220 may include contacts, trenches, vias, interconnects, columns, pillars, single damascene structures, and/or dual damascene structures, among other examples. The one or more metallization layers 220 may include tungsten (W), cobalt (Co), titanium (Ti), copper (Cu), gold (Au), silver (Ag), molybdenum (Mo), ruthenium (Ru), a metal alloy, and/or another type of electrically conductive material, among other examples.

On the backside of the substrate 202, a buffer layer 222 may be included. The buffer layer 222 may include one or more dielectric materials, such as a silicon oxide (SiOₓ), a silicon nitride (SiₓN_{y}), a silicon carbide (SiCₓ), a silicon carbon nitride (SiCN), and/or a silicon oxynitride (SiON), among other examples. In some implementations, the buffer layer 222 is in direct contact with the isolation structure 206.

As further shown in FIG. 2A, isolation regions 224 (e.g., shallow trench isolation (STI) regions) are formed in the substrate 202 at or near an interface between the substrate 202 and the interconnect layer 216. An isolation region 224 may include dielectric material such as a silicon oxide (SiOₓ), a silicon nitride (SiₓN_{y}), a silicon oxynitride (SiON), fluoride-doped silicate glass (FSG), a low dielectric constant (low-k) dielectric material, and/or another suitable insulating material. In addition to the isolation regions 224, doped implant regions 226 are formed in the substrate 202. The doped implant regions 226 are disposed between end portions of the isolation structure 206 and the isolation regions 224. In some implementations, a doped implant region 226 may be doped with one or more dopants, such as a p-type material (e.g., boron (B) or germanium (Ge), among other examples), or an n-type material (e.g., phosphorous (P), arsenic (As), bismuth (Bi), and/or antimony (Sb), among other examples).

The buffer layer 222 may include an approximately flat layer that provides an approximately flat dielectric substrate on which a nano-prism structure 228 may be formed. The nano-prism structure 228 may be formed over the pixel sensors 104 of the pixel sensor array 102, and may be disposed on and in direct contact with the buffer layer 222. As indicated above, the nano-prism structure 228 may be included to control the speed and angles of incident light traveling through different portions of the nano-prism structure 228 so that the light is directed to a focal point where a photodiode 204 may be located.

The nano-prism structure 228 may include a material layer 230 (e.g., nano-prism layer) including a first material having a first refractive index n₁. In some implementations, the nano-prism structure 228 also includes a plurality of columnar portions 232 (e.g., fill portions) in the material layer 230. FIG. 2B illustrates a top view of the nano-prism structure 228 formed over four pixel sensors 104. As shown in FIGS. 2A and 2B, the plurality of columnar portions 232 may be alternately arranged with portions of the material layer 230 in both the x-direction and the y-direction. The plurality of columnar portions 232 may include a second material having a second refractive index n₂. The second refractive index n₂ may be greater than the first refractive index n₁. In some implementations, the material layer 230 includes a silicon oxide (e.g., SiO₂), and the plurality of columnar portions 232 include a titanium oxide (e.g., TiO₂), a tantalum oxide (e.g., Ta₂O₅), an aluminum oxide (Al₂O₃), a hafnium oxide (e.g., HfO₂), a silicon nitride (e.g., Si₃N₄), and/or a silicon carbide (e.g., SiC), each of which has a greater refractive index than that of a silicon oxide (e.g., SiO₂). Other combinations of materials (e.g., nano-prism materials) for the material layer 230 and the plurality of columnar portions 232 where the second refractive index n₂ is greater than the first refractive index n₁ may be used.

In accordance with the following formula (1):

$$n = \frac{c}{v} , \qquad ( 1 )$$

where n is the refraction index, c is the speed of light in a vacuum, and vis the speed of light in the medium, the speed of light in the medium (v) decreases when the refractive index (n) increases. Accordingly, the speed of light in the medium (v) can be controlled based on the materials used for the material layer 230 and the plurality of columnar portions 232.

The width (e.g., x-direction dimension) of two or more columnar portions 232 may vary with respect to each other. In some cases, the width of two or more columnar portions 232 may be the same. The spacing (e.g., x-direction or y-direction dimension) between a first set of adjacent columnar portions 232 may vary or be the same with respect to the spacing between a second set of adjacent columnar portions 232. The shape of the columnar portions 232 may be for example, rectangular, square, trapezoidal, or another shape.

FIG. 2C illustrates another example implementation 234 of a portion of the pixel sensor array 102 of the image sensor device 100 that includes adjacent pixel sensors 104. As shown in FIG. 2C, the example implementation 234 of a portion of the pixel sensor array 102 is similar to the example implementation 200 of a portion of the pixel sensor array 102. However, in the example implementation 234, the nano-prism structure 228 includes the material layer 230, an additional material layer 236 (e.g., nano-prism layer), and columnar portions 232a, 232b, and 232c. The additional material layer 236 is stacked on the material layer 230 in a vertical direction (e.g., z-direction). The inclusion of the additional material layer 236 may increase total internal reflection of light incident on the nano-prism structure of the example implementation 234 in comparison to the nano-prism structure 228 of the example implementation 200 including the material layer 230, but not the additional material layer 236.

The columnar portions 232a, 232b, and 232c are formed through the additional material layer 236, and in the material layer 230. The columnar portions 232a, 232b, and 232c have widths (x-direction dimensions) D1, D2, and D3, respectively, where D1<D2<D3. In addition, the columnar portions 232a, 232b, and 232c are arranged in a repeating pattern (e.g., columnar portion 232a (width D1), columnar portion 232b (width D2), columnar portion 232c (width D3), columnar portion 232b (width D2)) according to respective lateral (x-direction) dimensions of the columnar portions 232a, 232b, and 232c. In some implementations, the ratio of D1:D2:D3 may be, for example, 1:2:4, 1:2:6, or 1:4:8. However, other values for the ratio of D1:D2:D3 are within the scope of the present disclosure.

As shown in FIG. 2C the width of respective columnar portions 232a, 232b, and 232c increases along the x-direction (e.g., D1 to D3) for a first set of the columnar portions 232a, 232b, and 232c, and then decreases along the x-direction (e.g., D3 to D1) for a second set of the columnar portions 232a, 232b, and 232c.

In the example implementation 234, the material layer 230 includes a first material having a first refractive index n₁, the additional material layer 236 includes a second material having a second refractive index n₂, and the columnar portions 232a, 232b, and 232c each include a third material having a third refractive index n₃. In this case, n₃>n₂>n₁. In some implementations, the material layer 230 includes a silicon oxide (e.g., SiO₂), the additional material layer 236 a tantalum oxide (e.g., TaO₅), which has a greater refractive index than that of a silicon oxide (e.g., SiO₂), and the columnar portions 232a, 232b, and 232c include a titanium oxide (e.g., TiO₂), which has a greater refractive index than that of a tantalum oxide (e.g., TaO₅), and of a silicon oxide (e.g., SiO₂). Other combinations of materials (e.g., nano-prism materials) for the material layer 230, the additional material layer 236, and the columnar portions 232a, 232b, and 232c where n₃>n₂>n₁ may be used. The shape of the columnar portions 232a, 232b, and 232c in the example implementation 234 is shown as rectangular. However, the columnar portions 232a, 232b, and 232c may be for example, square, trapezoidal, or another shape.

FIG. 2D illustrates another example implementation 238 of a portion of the pixel sensor array 102 of the image sensor device 100 that includes adjacent pixel sensors 104. As shown in FIG. 2D, the example implementation 238 of a portion of the pixel sensor array 102 is similar to the example implementation 234 of a portion of the pixel sensor array 102. However, in the example implementation 238, the nano-prism structure 228 includes columnar portions 232d, 232e, and 232f, which are similar to the columnar portions 232a, 232b, and 232c, but have a trapezoidal shape. The columnar portions 232d, 232e, and 232f are formed through the additional material layer 236, and in the material layer 230. The columnar portions 232d, 232e, and 232f have widths (x-direction dimensions) D4, D5, and D6, respectively, where D4<D5<D6. In addition, the columnar portions 232d, 232e, and 232f are arranged in a repeating pattern (e.g., columnar portion 232d (width D4), columnar portion 232e (width D5), columnar portion 232f (width D6), columnar portion 232e (width D5)) according to respective lateral (x-direction) dimensions of the columnar portions 232d, 232e, and 232f. In some implementations, the ratio of D4:D5:D6 may be, for example, 1:2:4, 1:2:6, or 1:4:8. However, other values for the ratio of D4:D5:D6 are within the scope of the present disclosure.

Similar to the example implementation 234, in the example implementation 238, the material layer 230 includes a first material having a first refractive index n₁, the additional material layer 236 includes a second material having a second refractive index n₂, and the columnar portions 232a, 232b, and 232c each include a third material having a third refractive index n₃, where n₃>n₂>n₁.

The trapezoidal shape of the columnar portions 232d, 232e, and 232f in the example implementation 238 in comparison to the rectangular shape of the columnar portions 232a, 232b, and 232c in the example implementation 234 may change the deflection angles of the light and the focal point of the light traveling through the columnar portions 232a, 232b, and 232c.

FIG. 2E illustrates another example implementation 240 of a portion of the pixel sensor array 102 of the image sensor device 100 that includes adjacent pixel sensors 104. As shown in FIG. 2E, the example implementation 240 of a portion of the pixel sensor array 102 is similar to the example implementation 240 of a portion of the pixel sensor array 102 in that the nano-prism structure 228 includes columnar portions in the material layer 230 and the additional material layer 236. However, in the example implementation 240, the columnar portions 232g and 232h are only formed in the additional material layer 236, while the columnar portions 232i are formed in the material layer 230 and in the additional material layer 236. The limitations on the vertical dimension (e.g., z-direction dimension) of the columnar portions 232g and 232h in the example implementation 240 in comparison to the columnar portions 232d and 232e in the example implementation 238 may increase the speed of the light traveling through the columnar portions 232g and 232h and subsequently into the material layer 230, where the material layer 230 has a lower refractive index than that of the columnar portions 232g and 232h. In addition, the different vertical dimension of the columnar portions 232g and 232h may change the deflection angles of the light as well as the focal point of the light.

As indicated above, FIGS. 2A-2E are provided as examples. Other examples may differ from what is described with regard to FIGS. 2A-2E.

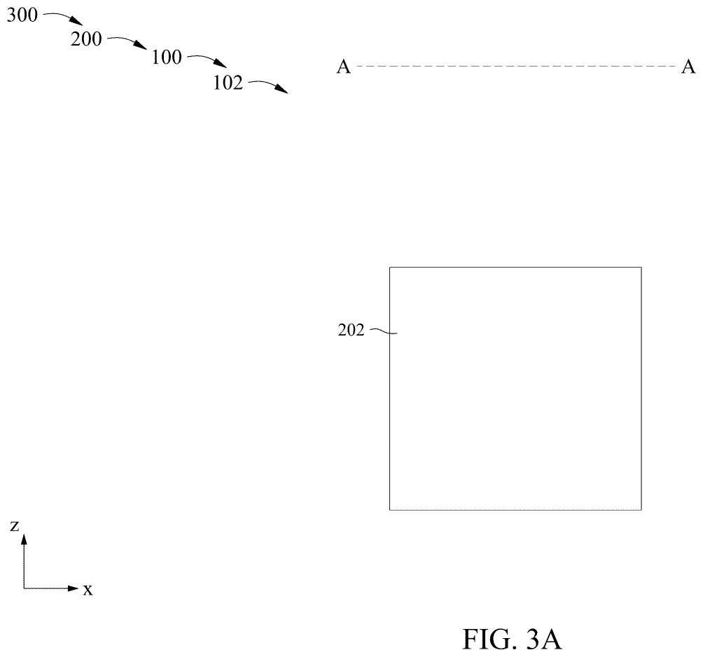

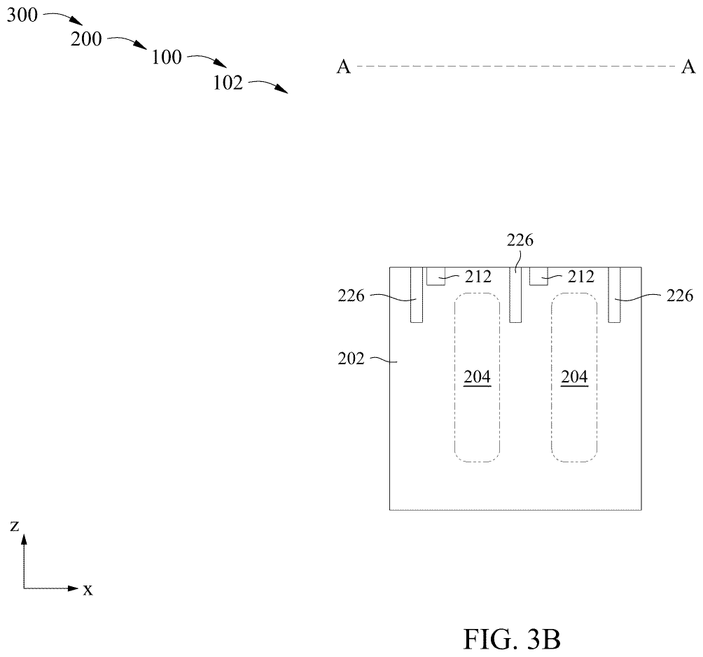

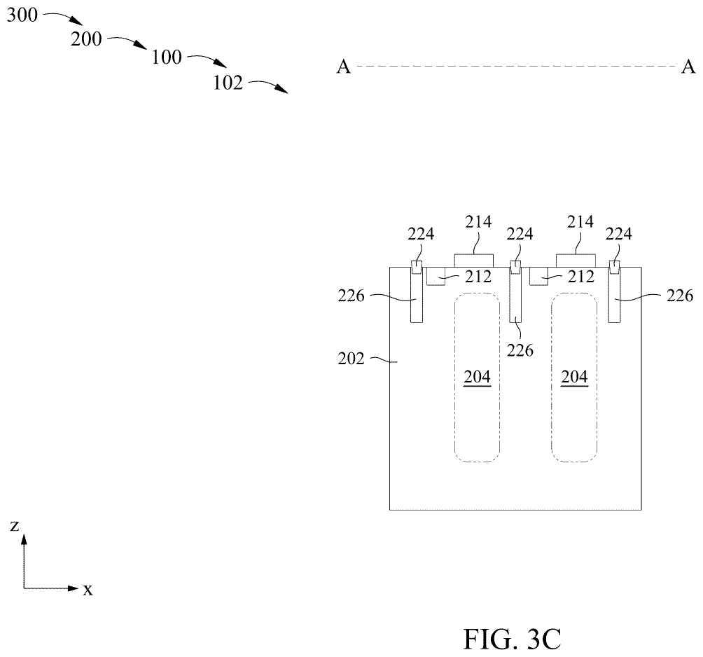

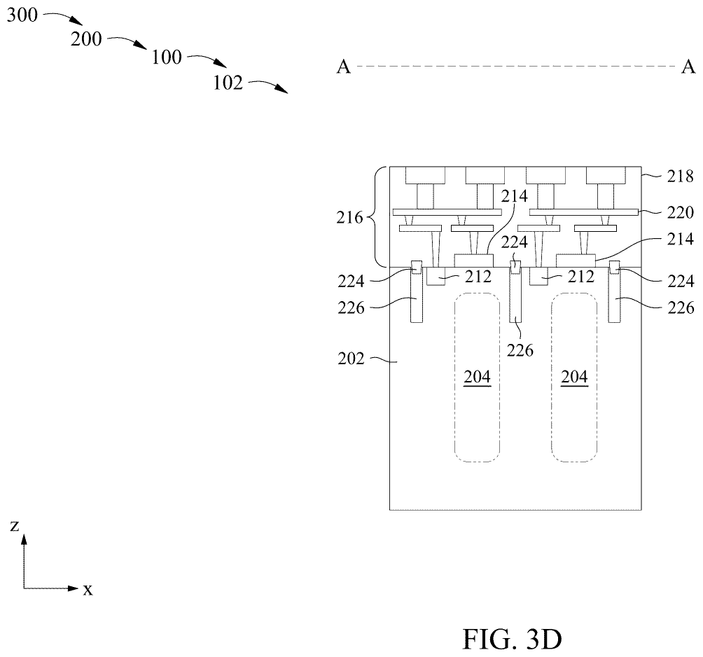

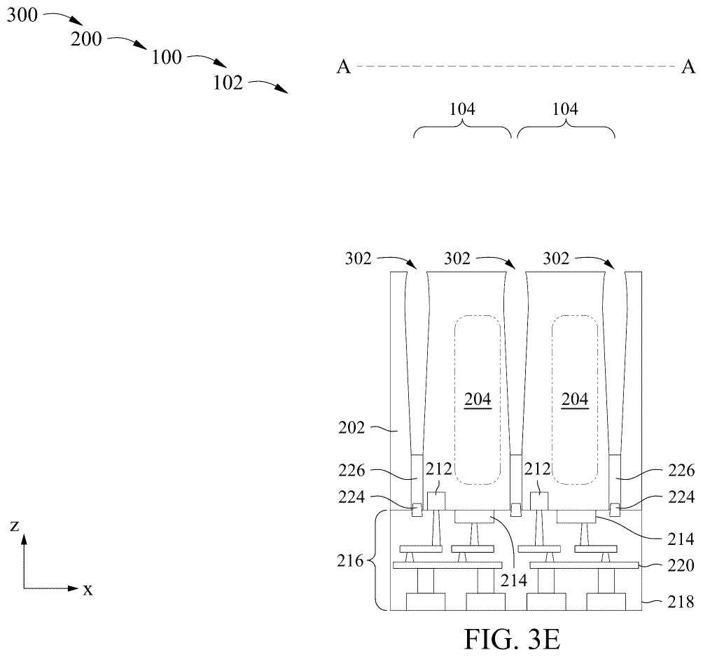

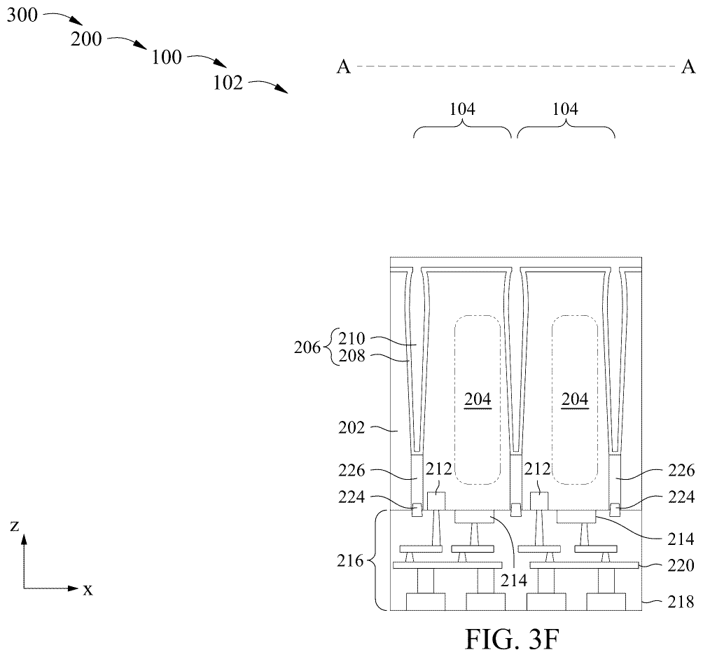

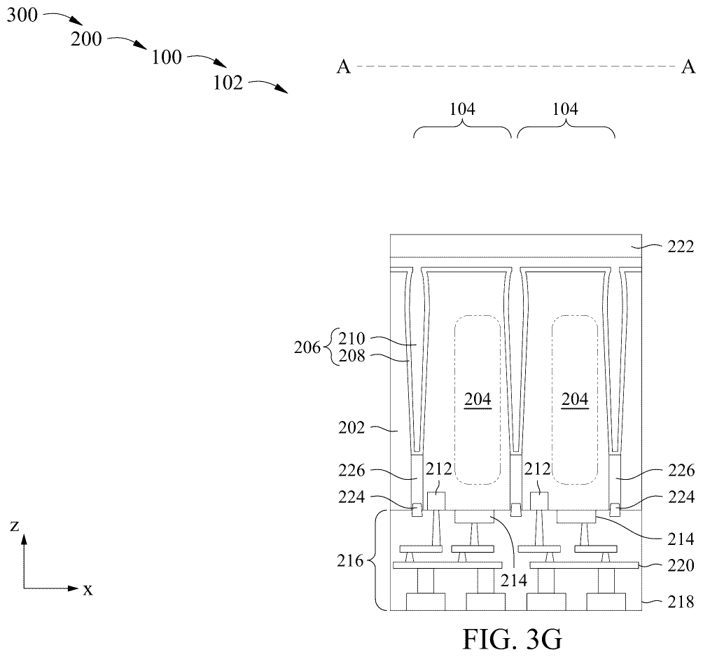

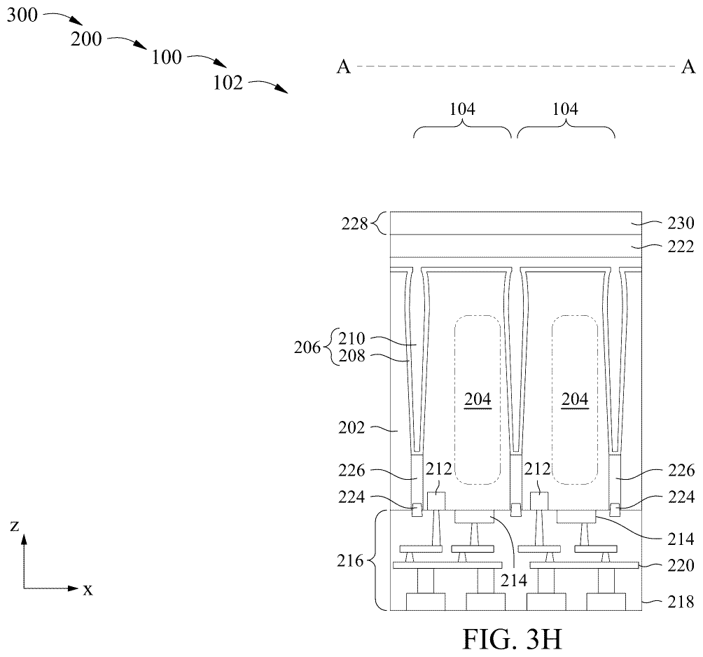

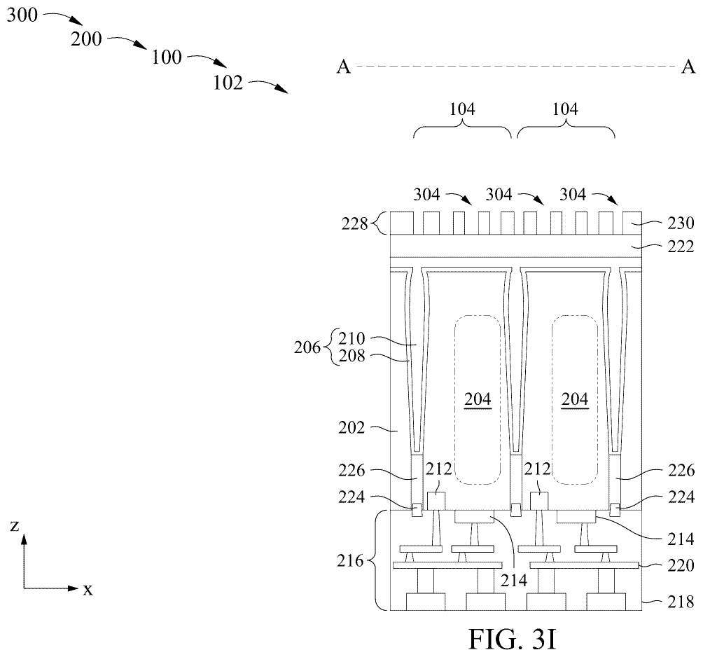

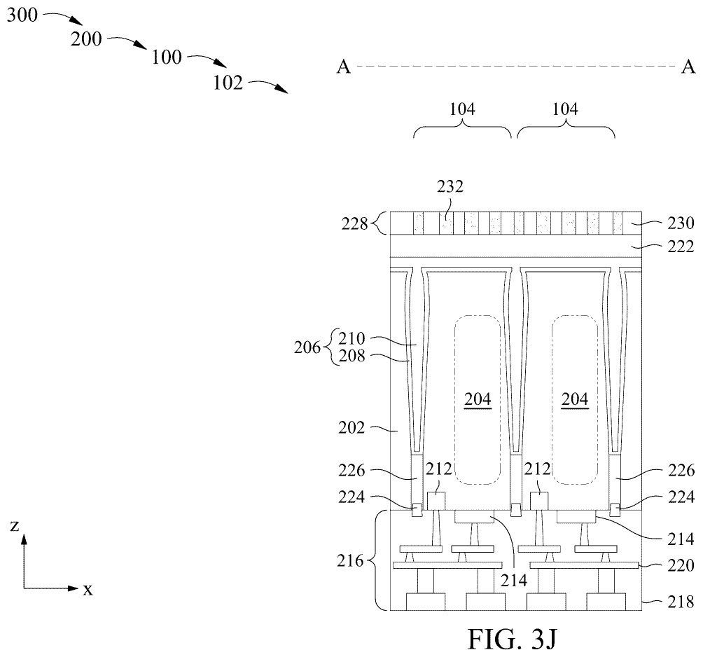

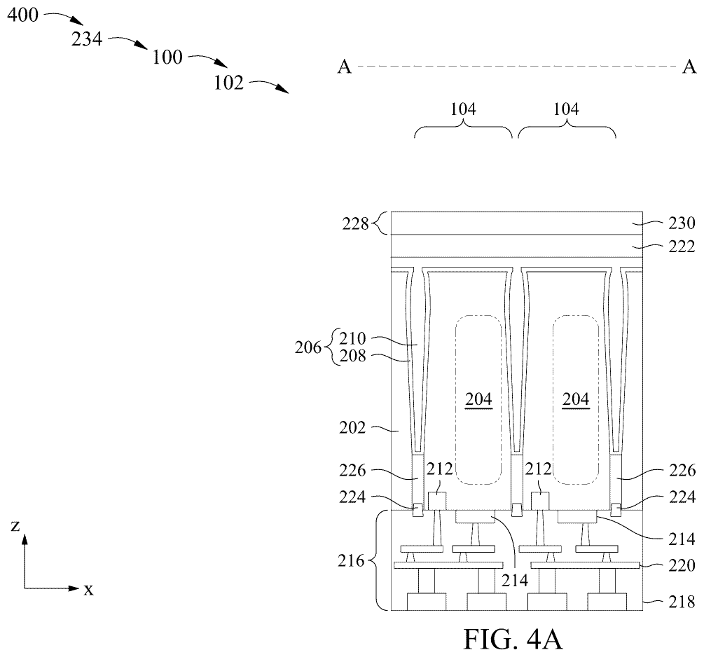

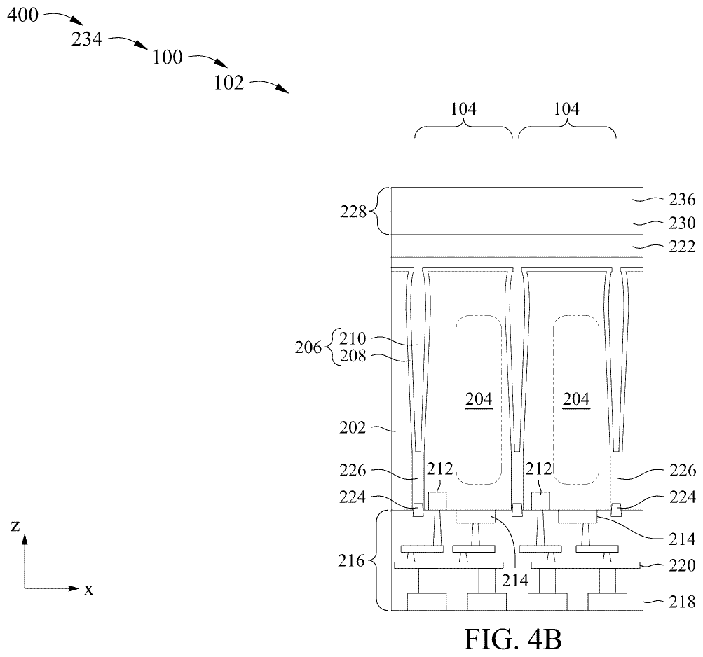

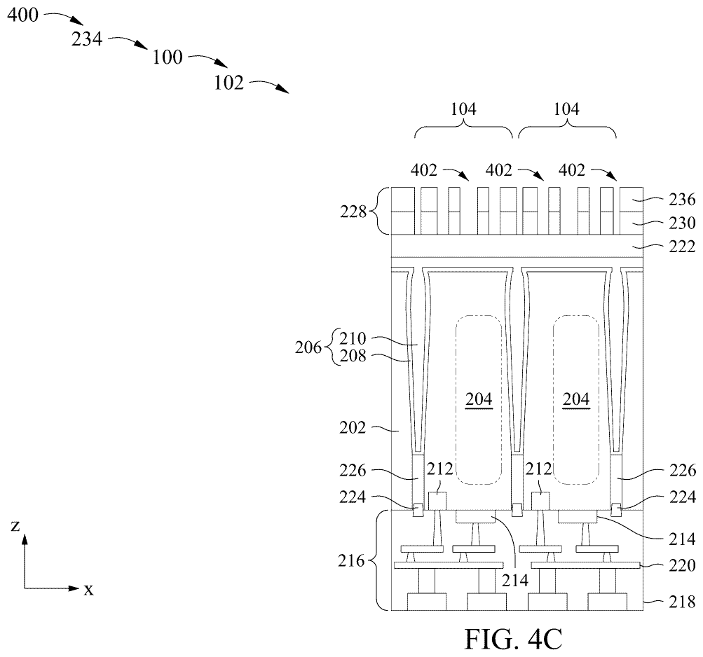

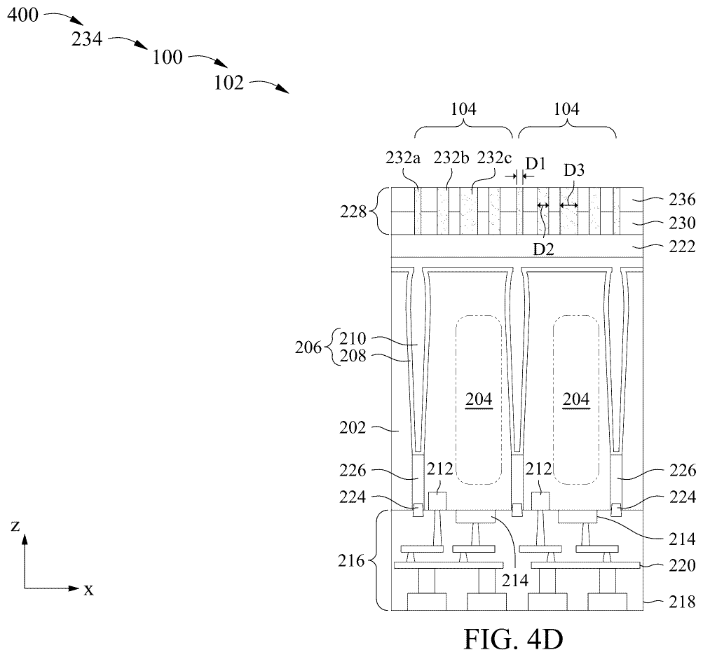

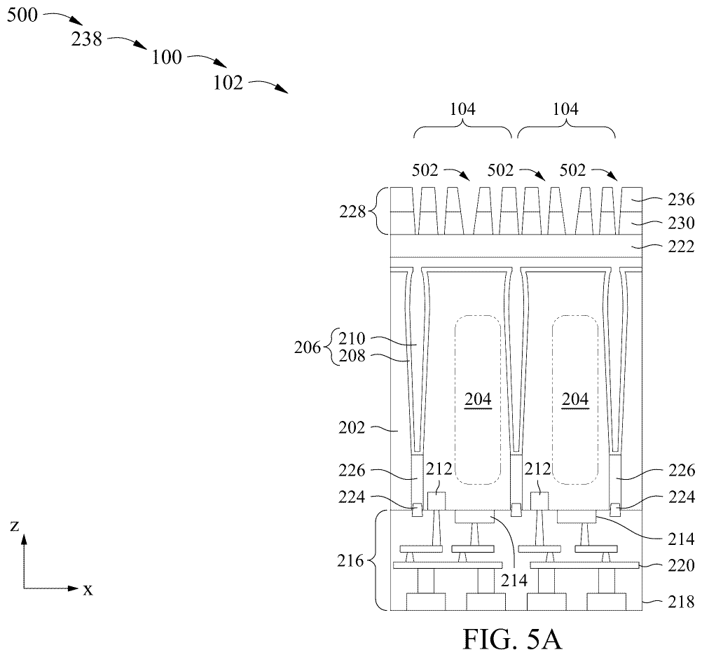

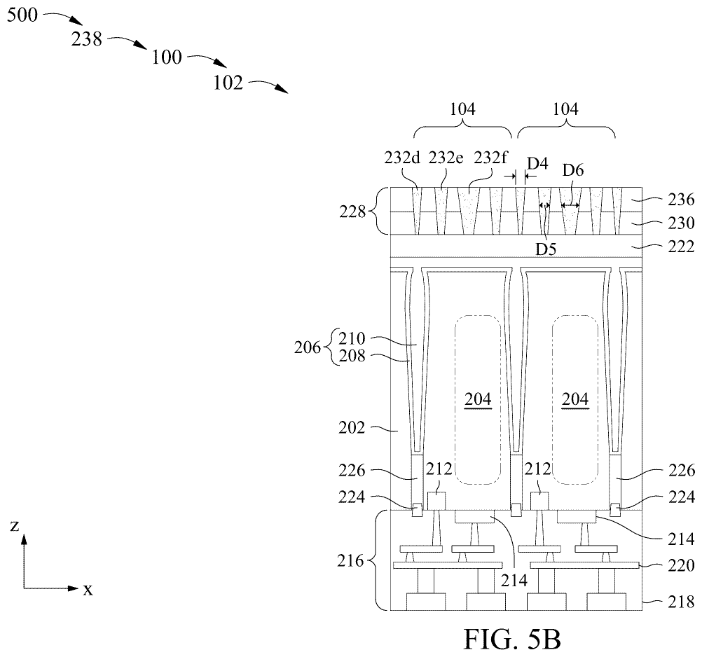

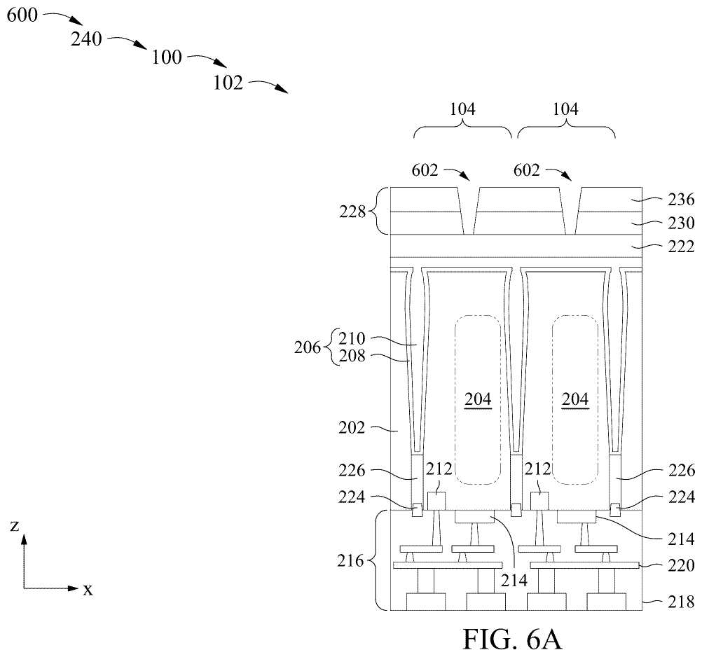

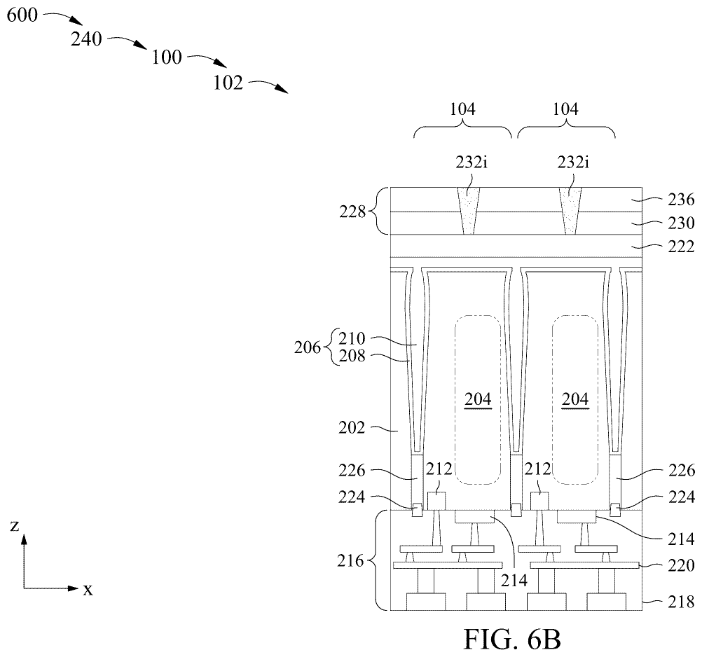

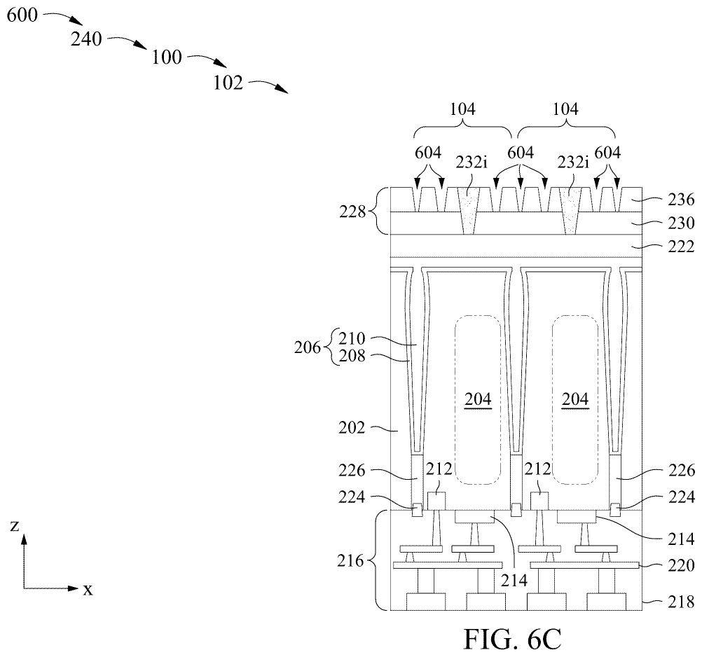

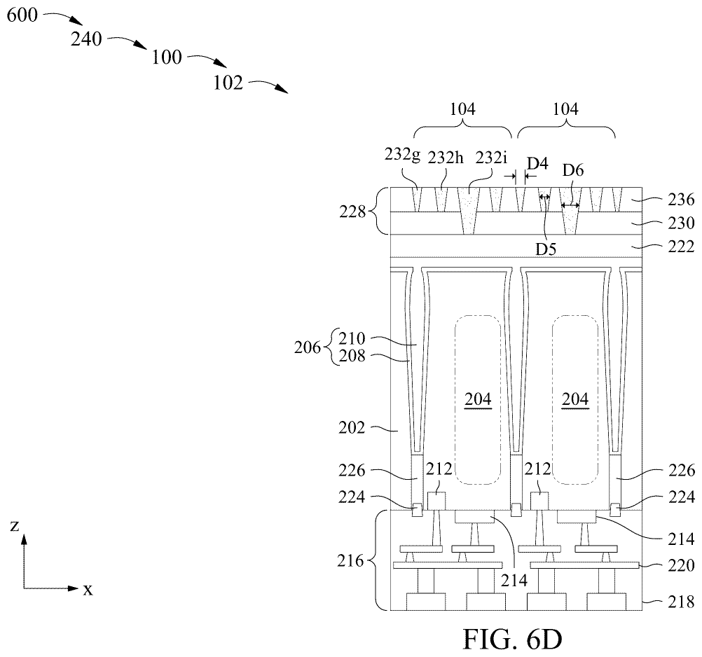

FIGS. 3A-3J are diagrams of an example implementation 300 of forming an image sensor device described herein. While the example implementation 300 includes forming the pixel sensor array 102 in the image sensor device 100 of the example implementation 200 described herein, the semiconductor processing techniques may be used to form at least portions of another pixel sensor array described herein, such as one or more of a pixel sensor arrays 102 of the example implementations 234, 238, and 240 described in connection with FIGS. 4A-4D, FIGS. 5A and 5B, and/or FIGS. 6A and 6B, among other examples. In some implementations, one or more of the semiconductor processing operations described in connection with FIGS. 3A-3J may be performed using one or more semiconductor processing tools, such as a deposition tool, an exposure tool, a developer tool, an etch tool, a planarization tool, a plating tool, an ion implantation tool, and/or a bonding tool, among other examples.

Turning to FIG. 3A, one or more of the semiconductor processing operations in the example implementation 300 may be performed in connection with the substrate 202. The substrate 202 may be provided as a semiconductor wafer or another type of semiconductor work piece.

As shown in FIG. 3B, a plurality of regions of the substrate 202 may be doped to form photodiodes 204 for the pixel sensors 104, and to form the doped implant regions 226. An ion implantation tool may be used to dope the substrate 202 to form one or more n-type regions and/or one or more p-type regions of the photodiodes 204. The ion implantation tool may be used to dope the substrate 202 to form one or more n-type regions and/or one or more p-type regions of the doped implant regions 226. The ion implantation tool may be used to implant p ions in the substrate 202 to form the p-type region(s) and/or may implant n+ ions in the substrate 202 to form the n-type region(s).

As further shown in FIG. 3B, one or more regions of the substrate 202 may be doped to form the FD nodes 212 of the pixel sensors 104. In some implementations, an ion implantation tool may be used to dope by implanting n+ ions in the substrate 202 to form the FD nodes 212.

As shown in FIG. 3C, transfer gates 214 of the pixel sensors 104 may be formed over the front side surface of the substrate 202. In some implementations, a gate dielectric layer may be formed on the front side surface of the substrate 202, and the transfer gates 214 may be formed over and/or on the gate dielectric layer. In some implementations, a deposition tool is used to deposit the transfer gates 214. In some implementations, the transfer gates 214 may include polysilicon that is doped with one or more types of dopants. In some implementations, the transfer gates 214 may include high-k dielectric and metal materials (e.g., metal gates or MGs).

As further shown in FIG. 3C, the isolation regions 224 are formed over the doped implant regions 226. The isolation regions 224 may be formed by using an etch tool to remove portions of the substrate 202 to form trenches in the substrate 202, and using a deposition tool to deposit dielectric material in the trenches to form the isolation regions 224. An etch tool may be used to recess portions of the substrate 202 around the isolation regions 224.

As shown in FIG. 3D, an interconnect layer 216 may be formed above the front side surface of the substrate 202. Forming the interconnect layer 216 may include forming one or more dielectric layers 218 and forming one or more metallization layers 220 in the one or more dielectric layers 218. For example, a first dielectric layer 218 may be formed and patterned to form recesses in the first dielectric layer 218, and a first metallization layer 220 may be formed in the recesses in the first dielectric layer 218. Subsequent layers of the interconnect layer 216 may be formed in a similar manner.

A deposition tool may be used to deposit the dielectric layer(s) 218 using a physical vapor deposition (PVD) technique, an atomic layer deposition (ALD) technique, a chemical vapor deposition (CVD) technique, an oxidation technique, and/or another type of deposition technique. In some implementations, a planarization tool may be used to planarize the dielectric layer(s) 218 after the dielectric layer(s) 218 are deposited.

In some implementations, a pattern in a photoresist layer is used to etch a dielectric layer 218 to form the recesses in the dielectric layer 218 for the metallization layers 220. In these implementations, a deposition tool may be used to form the photoresist layer on a dielectric layer 218. An exposure tool may be used to expose the photoresist layer to a radiation source to pattern the photoresist layer. A developer tool may be used to develop and remove portions of the photoresist layer to expose the pattern. An etch tool may be used to etch the dielectric layer 218 based on the pattern to form the recesses. In some implementations, the etch operation includes dry etch operation (e.g., a plasma-based etch operation, a gas-based etch operation), a wet chemical etch operation, and/or another type of etch operation. In some implementations, a photoresist removal tool may be used to remove the remaining portions of the photoresist layer (e.g., using a chemical stripper, plasma ashing, and/or another technique). In some implementations, a hard mask layer is used as an alternative technique for etching the dielectric layer 218 based on a pattern.

A deposition tool may be used to deposit the metallization layers 220 using a PVD technique, an ALD technique, a CVD technique, an electroplating (e.g., an electro-chemical plating) technique, and/or another type of deposition technique. In some implementations, a planarization tool may be used to planarize the metallization layers 220 after the metallization layers 220 are deposited. In some implementations, a seed layer is first deposited, and a metallization layer 220 is formed on the seed layer. In some implementations, one or more liners (e.g., a barrier layer, an adhesion layer) is first deposited, and a metallization layer 220 is formed on the one or more liners.

As shown in FIG. 3E, backside processing may be performed on the backside surface of the substrate 202. Recesses 302 may be formed into the substrate 202 from the backside surface of the substrate 202. In some implementations, a pattern in a photoresist layer is used to pattern the recesses 302. The recesses 302 may include a plurality of interconnected trenches that extend into the substrate 202 to form a grid around the photodiodes 204 and, in some implementations, around the FD nodes 212.

A deposition tool may be used to form the photoresist layer on the backside surface of the substrate 202. An exposure tool may be used to expose the photoresist layer to a radiation source to pattern the photoresist layer. A developer tool may be used to develop and remove portions of the photoresist layer to expose the pattern. An etch tool may be used to etch the substrate 202 based on the pattern to form the recesses 302. In some implementations, the etch operation includes a plasma etch operation, a wet chemical etch operation, and/or another type of etch operation. In some implementations, a photoresist removal tool may be used to remove the remaining portions of the photoresist layer (e.g., using a chemical stripper, plasma ashing, and/or another technique). Alternatively, the pattern in the photoresist layer may be used to transfer the pattern to a hard mask layer that is used for forming the recesses 302.

In some implementations, a cyclic etch technique is used to form the recesses 302 to have a relatively high aspect ratio between the depth of the recesses 302 and the lateral width of the recesses 302. For example, a cyclic etch technique is used to form the recesses 302 such that the recesses 302 have an aspect ratio between the depth of the recesses 302 and the lateral width of the recesses 302 that is at least approximately 8:1 or greater. However, other values for the aspect ratio of the recesses 302 are within the scope of the present disclosure. The cyclic etch technique may include a plurality of deposition and etch cycles that are performed using protective liners to minimize lateral etching. For example, a deposition and etch cycle may include etching a recess 302 to a first depth in the substrate 202, forming a protective liner on the sidewalls and bottom surface of the recess 302, etching the protective liner to remove the protective liner from the bottom surface of the recess 302, and etching the bottom of the recess 302 to increase the depth of the recess 302 to a second depth while the protective liner protects the sidewalls of the recess 302 from lateral etching. Additional cycles may be performed to achieve a particular depth for the recesses 302.

As shown in FIG. 3F, the recesses 302 are filled with one or more liners 208 and a fill layer 210 to form the isolation structure 206 in the recesses 302. The isolation structure 206 may extend into the substrate 202 and laterally around the photodiodes 204. As further shown in FIG. 3F, in some implementations, the material of the liner(s) 208 and/or the material of the fill layer 210 may be deposited over the backside surface of the substrate 202.

A deposition tool may be used to deposit the one or more liners 208 in the recesses 302 using a conformal deposition technique such as ALD or CVD, among other examples. The one or more liners 208 may be conformally deposited on the sidewalls and the bottom surface of the recesses 302 such that the one or more liners 208 conform to the profile of the recesses 302. A deposition tool may be used to deposit the fill layer 210 using a PVD technique, an ALD technique, a CVD technique, an oxidation technique, and/or another type of deposition technique.

In some implementations, a planarization tool may be used to perform a planarization operation (e.g., a chemical mechanical planarization (CMP) operation) to planarize the backside of the substrate 202 to remove the one or more liners 208 and/or the fill layer 210 from the backside surface of the substrate 202. In some implementations, the planarization operation is omitted (or stops before the one or more liners 208 and/or the fill layer 210 are removed from the backside surface of the substrate 202) such that the one or more liners 208 and/or the fill layer 210 remain on the backside surface of the substrate 202.

As shown in FIG. 3G, the buffer layer 222 may be formed on the fill layer 210 of the isolation structure 206. A deposition tool may deposit the buffer layer 222 using a PVD technique, an ALD technique, a CVD technique, an oxidation technique, and/or another suitable deposition technique. In some implementations, a planarization tool may be used to perform a planarization operation (e.g., a CMP operation) to planarize the buffer layer 222.

As shown in FIG. 3H, in order to form the nano-prism structure 228, the material layer 230 may be formed over and/or on the buffer layer 222. A deposition tool may deposit the material layer 230 using a PVD technique, an ALD technique, a CVD technique, an oxidation technique, and/or another suitable deposition technique. In these implementations, a planarization tool may be used to perform a planarization operation (e.g., a CMP operation) to planarize the material layer 230.

As shown in FIG. 3I, recesses 304 may be formed in the material layer 230. In some implementations, a pattern in a photoresist layer is used to pattern the recesses 304. The recesses 304 may include a plurality of trenches that extend into the material layer 230 and stop at the buffer layer 222.

A deposition tool may be used to form the photoresist layer on the exposed surface of the material layer 230. An exposure tool may be used to expose the photoresist layer to a radiation source to pattern the photoresist layer. A developer tool may be used to develop and remove portions of the photoresist layer to expose the pattern. An etch tool may be used to etch the material layer 230 based on the pattern to form the recesses 304. In some implementations, the etch operation includes a plasma etch operation, a wet chemical etch operation, and/or another type of etch operation. In some implementations, a photoresist removal tool may be used to remove the remaining portions of the photoresist layer (e.g., using a chemical stripper, plasma ashing, and/or another technique). Alternatively, the pattern in the photoresist layer may be used to transfer the pattern to a hard mask layer that is used for forming the recesses 304.

As shown in FIG. 3J, the recesses 304 are filled with the material of the columnar portions 232 to form the columnar portions 232 in the recesses 304. A deposition tool may be used to deposit the material of the columnar portions 232 in the recesses 304 using a PVD technique, ALD technique, or CVD technique, among other examples. In some implementations, as described in more detail herein, in the case of columnar portions with multiple materials, the material of the columnar portions 232 may be conformally deposited on the sidewalls and the bottom surfaces of the recesses 304 and on underlying layers of columnar portion material using a conformal deposition technique such as ALD or CVD.

In some implementations, a planarization tool may be used to perform a planarization operation (e.g., a CMP operation) to planarize the material layer 230 to remove the material of the columnar portions 232 from an exposed surface of the material layer 230.

As shown in FIG. 3J, the nano-prism structure 228 is provided on the buffer layer 222. The nano-prism structure 228 is provided such that the nano-prism structure 228 is located above the photodiodes 204 of the pixel sensors 104.

In some implementations, the nano-prism structure 228 in the example implementation 200 is formed prior to being placed on the buffer layer 222. In these implementations, the nano-prism structure 228 is formed in a separate process, and then placed on the pixel sensor array 102 after manufacturing.

As indicated above, FIGS. 3A-3J are provided as an example. Other examples may differ from what is described with regard to FIGS. 3A-3J.

FIGS. 4A-4D are diagrams of an example implementation 400 of forming an image sensor device described herein. The example implementation 400 includes forming the pixel sensor array 102 in the image sensor device 100 of the example implementation 234 described herein. In some implementations, one or more of the semiconductor processing operations described in connection with FIGS. 4A-4D may be performed using one or more semiconductor processing tools, such as a deposition tool, an exposure tool, a developer tool, an etch tool, a planarization tool, a plating tool, an ion implantation tool, and/or a bonding tool, among other examples.

Turning to FIG. 4A, like what is shown in FIG. 3H, in order to form the nano-prism structure 228, the material layer 230 may be formed over and/or on the buffer layer 222. A deposition tool may deposit the material layer 230 using a PVD technique, an ALD technique, a CVD technique, an oxidation technique, and/or another suitable deposition technique. A planarization tool may be used to perform a planarization operation (e.g., a CMP operation) to planarize the material layer 230.

As shown in FIG. 4B, the additional material layer 236 may be formed over and/or on the material layer 230. A deposition tool may deposit the additional material layer 236 using a PVD technique, an ALD technique, a CVD technique, an oxidation technique, and/or another suitable deposition technique. A planarization tool may be used to perform a planarization operation (e.g., a CMP operation) to planarize the additional material layer 236.

As shown in FIG. 4C, recesses 402 may be formed in the additional material layer 236 and in the material layer 230. In some implementations, a pattern in a photoresist layer is used to pattern the recesses 402. The recesses 402 may include a plurality of trenches that extend into and through the additional material layer 236, and into the material layer 230 stopping at the buffer layer 222. As shown in FIG. 4C the width of respective recesses 402 increases along the x-direction for a first set of the recesses 402, and then decreases along the x-direction for a second set of the recesses 402.

A deposition tool may be used to form the photoresist layer on the exposed surface of the additional material layer 236. An exposure tool may be used to expose the photoresist layer to a radiation source to pattern the photoresist layer. A developer tool may be used to develop and remove portions of the photoresist layer to expose the pattern. An etch tool may be used to etch the additional material layer 236 and the material layer 230 based on the pattern to form the recesses 402. In some implementations, the etch operation includes a plasma etch operation, a wet chemical etch operation, and/or another type of etch operation. In some implementations, a photoresist removal tool may be used to remove the remaining portions of the photoresist layer (e.g., using a chemical stripper, plasma ashing, and/or another technique). Alternatively, the pattern in the photoresist layer may be used to transfer the pattern to a hard mask layer that is used for forming the recesses 402.

As shown in FIG. 4D, the recesses 402 are filled with the material of the columnar portions 232a, 232b, and 232c to form the columnar portions 232a, 232b, and 232c in the recesses 402. A deposition tool may be used to deposit the material of the columnar portions 232a, 232b, and 232c in the recesses 402 using a PVD technique, ALD technique, or CVD technique, among other examples. In some implementations, as described in more detail herein, in the case of columnar portions with multiple materials, the material of the columnar portions 232a, 232b, and 232c may be conformally deposited on the sidewalls and the bottom surfaces of the recesses 402 and on underlying layers of columnar portion material using a conformal deposition technique such as ALD or CVD.

In some implementations, a planarization tool may be used to perform a planarization operation (e.g., a CMP operation) to planarize the additional material layer 236 to remove the material of the columnar portions 232a, 232b, and 232c from an exposed surface of the additional material layer 236.

As shown in FIG. 4D, the nano-prism structure 228 is provided on the buffer layer 222. The nano-prism structure 228 is provided such that the nano-prism structure 228 is located above the photodiodes 204 of the pixel sensors 104.

In some implementations, the nano-prism structure 228 is formed prior to being placed on the buffer layer 222. In these implementations, the nano-prism structure 228 in the example implementation 234 is formed in a separate process, and then placed on the pixel sensor array 102 after manufacturing.

As indicated above, FIGS. 4A-4D are provided as an example. Other examples may differ from what is described with regard to FIGS. 4A-4D.

FIGS. 5A and 5B are diagrams of an example implementation 500 of forming an image sensor device described herein. The example implementation 500 includes forming the pixel sensor array 102 in the image sensor device 100 of the example implementation 238 described herein. In some implementations, one or more of the semiconductor processing operations described in connection with FIGS. 5A and 5B may be performed using one or more semiconductor processing tools, such as a deposition tool, an exposure tool, a developer tool, an etch tool, a planarization tool, a plating tool, an ion implantation tool, and/or a bonding tool, among other examples.

Turning to FIG. 5A, similar to what is shown in FIG. 4C, recesses 502 may be formed in the additional material layer 236 and in the material layer 230. In contrast to what is shown in FIG. 4C, the recesses 502 have a trapezoidal shape with a decreasing width (e.g., x-direction dimension) in the downward z-direction instead of the rectangular shape of the recesses 402. In some implementations, a pattern in a photoresist layer is used to pattern the recesses 502. The recesses 502 may include a plurality of trenches that extend into and through the additional material layer 236, and into the material layer 230 stopping at the buffer layer 222.

A deposition tool may be used to form the photoresist layer on the exposed surface of the additional material layer 236. An exposure tool may be used to expose the photoresist layer to a radiation source to pattern the photoresist layer. A developer tool may be used to develop and remove portions of the photoresist layer to expose the pattern. An etch tool may be used to etch the additional material layer 236 and the material layer 230 based on the pattern to form the recesses 502. In some implementations, the etch operation includes a plasma etch operation, a wet chemical etch operation, and/or another type of etch operation. In some implementations, a photoresist removal tool may be used to remove the remaining portions of the photoresist layer (e.g., using a chemical stripper, plasma ashing, and/or another technique). Alternatively, the pattern in the photoresist layer may be used to transfer the pattern to a hard mask layer that is used for forming the recesses 502.

As shown in FIG. 5B, the recesses 502 are filled with the material of the columnar portions 232d, 232e, and 232f to form the columnar portions 232d, 232e, and 232f in the recesses 502. A deposition tool may be used to deposit the material of the columnar portions 232d, 232e, and 232f in the recesses 502 using a PVD technique, ALD technique, or CVD technique, among other examples. In some implementations, as described in more detail herein, in the case of columnar portions with multiple materials, the material of the columnar portions 232d, 232e, and 232f may be conformally deposited on the sidewalls and the bottom surfaces of the recesses 502 and on underlying layers of columnar portion material using a conformal deposition technique such as ALD or CVD.

In some implementations, a planarization tool may be used to perform a planarization operation (e.g., a CMP operation) to planarize the additional material layer 236 to remove the material of the columnar portions 232d, 232e, and 232f from an exposed surface of the additional material layer 236.

As shown in FIG. 5B, the nano-prism structure 228 is provided on the buffer layer 222. The nano-prism structure 228 is provided such that the nano-prism structure 228 is located above the photodiodes 204 of the pixel sensors 104.

In some implementations, the nano-prism structure 228 in the example implementation 238 is formed prior to being placed on the buffer layer 222. In these implementations, the nano-prism structure 228 is formed in a separate process, and then placed on the pixel sensor array 102 after manufacturing.

As indicated above, FIGS. 5A and 5B are provided as an example. Other examples may differ from what is described with regard to FIGS. 5A and 5B.

FIGS. 6A-6D are diagrams of an example implementation 600 of forming an image sensor device described herein. The example implementation 600 includes forming the pixel sensor array 102 in the image sensor device 100 of the example implementation 240 described herein. In some implementations, one or more of the semiconductor processing operations described in connection with FIGS. 6A-6D may be performed using one or more semiconductor processing tools, such as a deposition tool, an exposure tool, a developer tool, an etch tool, a planarization tool, a plating tool, an ion implantation tool, and/or a bonding tool, among other examples.

Turning to FIG. 6A, first recesses 602 may be formed in the additional material layer 236 and in the material layer 230.

In some implementations, a pattern in a first photoresist layer is used to pattern the first recesses 602. The first recesses 602 may include a plurality of trenches that extend into and through the additional material layer 236, and into the material layer 230 stopping at the buffer layer 222.

A deposition tool may be used to form the first photoresist layer on the exposed surface of the additional material layer 236. An exposure tool may be used to expose the first photoresist layer to a radiation source to pattern the first photoresist layer. A developer tool may be used to develop and remove portions of the first photoresist layer to expose the pattern. An etch tool may be used to etch the additional material layer 236 and the material layer 230 based on the pattern to form the first recesses 602. In some implementations, the etch operation includes a plasma etch operation, a wet chemical etch operation, and/or another type of etch operation. In some implementations, a photoresist removal tool may be used to remove the remaining portions of the first photoresist layer (e.g., using a chemical stripper, plasma ashing, and/or another technique). Alternatively, the pattern in the first photoresist layer may be used to transfer the pattern to a hard mask layer that is used for forming the first recesses 602.

As shown in FIG. 6B, the first recesses 602 are filled with the material of the columnar portions 232i to form the columnar portions 232i in the first recesses 602. A deposition tool may be used to deposit the material of the columnar portions 232i in the recesses 502 using a PVD technique, ALD technique, or CVD technique, among other examples. In some implementations, as described in more detail herein, in the case of columnar portions with multiple materials, the material of the columnar portions 232i may be conformally deposited on the sidewalls and the bottom surfaces of the first recesses 602 and on underlying layers of columnar portion material using a conformal deposition technique such as ALD or CVD.

In some implementations, a planarization tool may be used to perform a planarization operation (e.g., a CMP operation) to planarize the additional material layer 236 to remove the material of the columnar portions 232i from an exposed surface of the additional material layer 236.

As shown in FIG. 6C, in some implementations, a pattern in a second photoresist layer is used to pattern the second recesses 604. The second recesses 604 may include a plurality of trenches that extend into the additional material layer 236, and stop at the material layer 230.

A deposition tool may be used to form the second photoresist layer on the exposed surface of the additional material layer 236. An exposure tool may be used to expose the second photoresist layer to a radiation source to pattern the second photoresist layer. A developer tool may be used to develop and remove portions of the second photoresist layer to expose the pattern. An etch tool may be used to etch the additional material layer 236 based on the pattern to form the second recesses 604. In some implementations, the etch operation includes a plasma etch operation, a wet chemical etch operation, and/or another type of etch operation. In some implementations, a photoresist removal tool may be used to remove the remaining portions of the second photoresist layer (e.g., using a chemical stripper, plasma ashing, and/or another technique). Alternatively, the pattern in the second photoresist layer may be used to transfer the pattern to a hard mask layer that is used for forming the second recesses 604.

As shown in FIG. 6D, the second recesses 604 are filled with the material of the columnar portions 232g and 232h to form the columnar portions 232g and 232h in the second recesses 604. A deposition tool may be used to deposit the material of the columnar portions 232g and 232h in the second recesses 604 using a PVD technique, ALD technique, or CVD technique, among other examples. In some implementations, as described in more detail herein, in the case of columnar portions with multiple materials, the material of the columnar portions 232g and 232h may be conformally deposited on the sidewalls and the bottom surfaces of the second recesses 604 and on underlying layers of columnar portion material using a conformal deposition technique such as ALD or CVD.

In some implementations, a planarization tool may be used to perform a planarization operation (e.g., a CMP operation) to planarize the additional material layer 236 to remove the material of the columnar portions 232g and 232h from an exposed surface of the additional material layer 236.

As shown in FIG. 6D, the nano-prism structure 228 is provided on the buffer layer 222. The nano-prism structure 228 is provided such that the nano-prism structure 228 is located above the photodiodes 204 of the pixel sensors 104.

In some implementations, the nano-prism structure 228 in the example implementation 240 is formed prior to being placed on the buffer layer 222. In these implementations, the nano-prism structure 228 is formed in a separate process, and then placed on the pixel sensor array 102 after manufacturing.

As indicated above, FIGS. 6A-6D are provided as an example. Other examples may differ from what is described with regard to FIGS. 6A-6D.

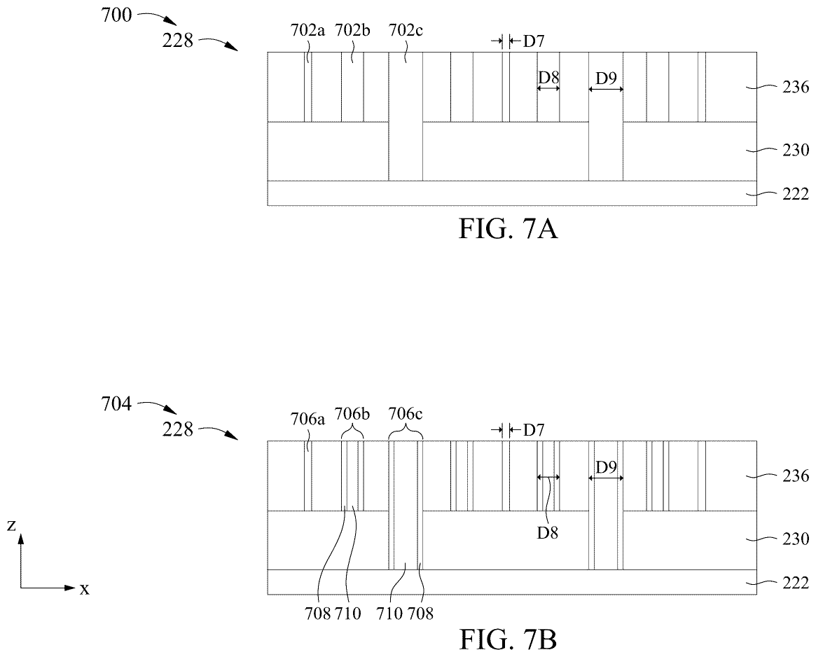

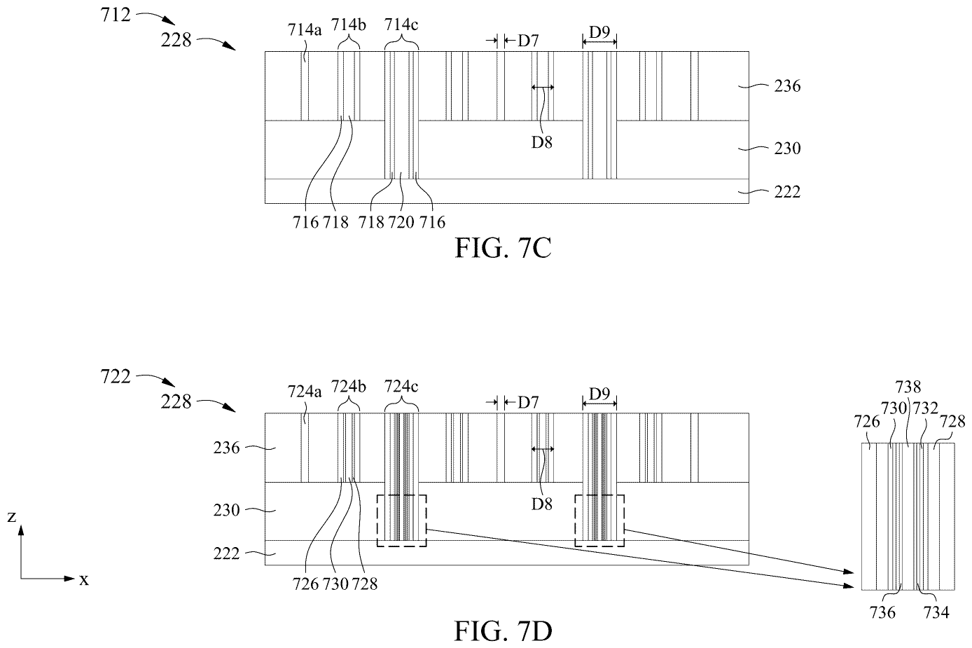

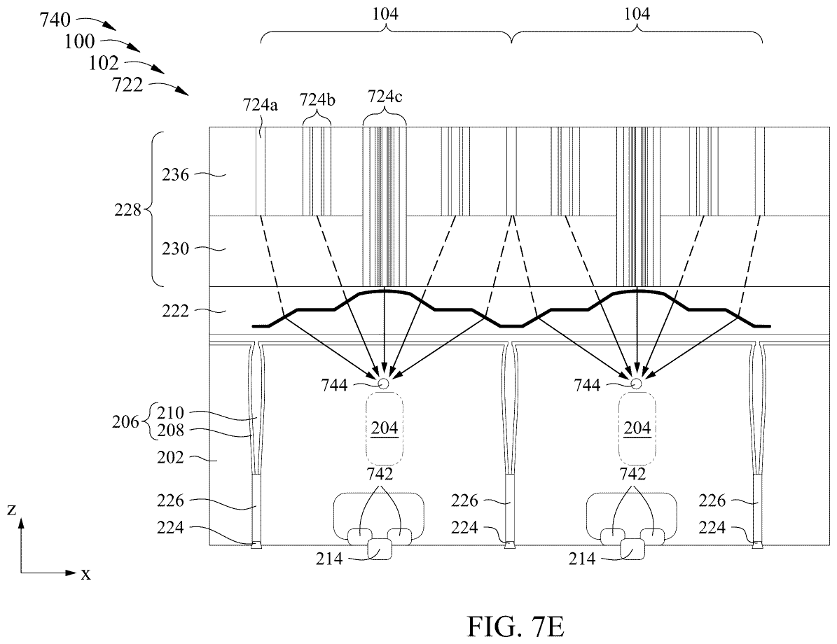

FIGS. 7A-7E are diagrams of example implementations of a portion of a pixel sensor array described herein. FIG. 7A illustrates an example implementation 700 of the nano-prism structure 228. As shown in FIG. 7A, the nano-prism structure 228 includes columnar portions in the material layer 230 and the additional material layer 236. The columnar portions 702a and 702b are only formed in the additional material layer 236, while the columnar portions 702c are formed in the material layer 230 and in the additional material layer 236. The limitations on the vertical dimension (e.g., z-direction dimension) of the columnar portions 702a and 702b in the example implementation 700 in comparison to the columnar portions formed through both of the additional material layer 236 and the material layer 230 may increase the speed of the light traveling through the columnar portions 702a and 702b and subsequently into the material layer 230, where the material layer 230 has a lower refractive index than that of the columnar portions 702a and 702b. In addition, the different vertical dimension of the columnar portions 702a and 702b from columnar portions formed through both of the additional material layer 236 and the material layer 230 may change the deflection angles of the light as well as the focal point of the light.

The columnar portions 702a, 702b, and 702c have widths (x-direction dimensions) D7, D8, and D9, respectively, where D7<D8<D9. In addition, the columnar portions 702a, 702b, and 702c are arranged in a repeating pattern (e.g., columnar portion 702a (width D7), columnar portion 702b (width D8), columnar portion 702c (width D9), columnar portion 702b (width D8)) according to respective lateral (x-direction) dimensions of the columnar portions 702a, 702b, and 702c. In some implementations, the ratio of D7:D8:D9 may be, for example, 1:2:4, 1:2:6, or 1:4:8. However, other values for the ratio of D7:D8:D9 are within the scope of the present disclosure.

In the example implementation 700, the material layer 230 includes a first material having a first refractive index n₁, the additional material layer 236 includes a second material having a second refractive index n₂, and the columnar portions 702a, 702b, and 702c each include a third material having a third refractive index n₃, where n₃>n₂>n₁. In some implementations, the material layer 230 includes a silicon oxide (e.g., SiO₂), the additional material layer 236 includes a tantalum oxide (e.g., TaO₅), which has a greater refractive index than that of a silicon oxide (e.g., SiO₂), and the columnar portions 702a, 702b, and 702c include a titanium oxide (e.g., TiO₂), which has a greater refractive index than that of a tantalum oxide (e.g., TaO₅), and of a silicon oxide (e.g., SiO₂). Other combinations of materials for the material layer 230, the additional material layer, and the columnar portions 702a, 702b, and 702c where n₃>m₂>n₁ may be used.

The rectangular shape (e.g., straight profile) of the columnar portions 702a, 702b, and 702c in the example implementation 700 may result in particular deflection angles and a particular focal point of light traveling through the columnar portions 702a, 702b, and 702c.

As shown in FIG. 7B, the example implementation 704 of the nano-prism structure 228 is similar to the example implementation 700 of the nano-prism structure 228. The example implementation 704 of the nano-prism structure 228 includes columnar portions 706a, 706b, and 706c, which are similar to the columnar portions 702a, 702b, and 702c, except that the columnar portions 706b and 706c each include a first material layer 708 and a second material layer 710. For example, portions of the first material layer 708 are on opposite lateral sides of the columnar portions 706b and 706c, and the second material layer 710 fills in a remaining interior area of the columnar portions 706b and 706c. The first material layer 708 may be conformally deposited in a recess, and the second material layer 710 may be conformally deposited on the first material layer 708 in the recess to form the columnar portions 706b and 706c. The columnar portions 706b and 706c including two material layers (e.g., first and second material layers 708 and 710) may reduce phase velocity in comparison to, for example, columnar portions 702b and 702c including one material layer.

In some implementations, the combination of materials for the material layer 230, the additional material layer 236, the columnar portions 706a, the first material layer 708, and the second material layer 710, may be any combination of nano-prism materials (e.g., a silicon oxide (e.g., SiO₂), a titanium oxide (e.g., TiO₂), a tantalum oxide (e.g., Ta₂O₅), an aluminum oxide (Al₂O₃), a hafnium oxide (e.g., HfO₂), a silicon nitride (e.g., Si₃N₄), and/or a silicon carbide (e.g., SiC)) where the refractive index of the columnar portions 706a, 706b, and 706c (e.g., n₃) is greater than the refractive index of the additional material layer 236 (e.g., n₂), which is greater than the refractive index of the material layer 230 (e.g., n₁).

As shown in FIG. 7C, the example implementation 712 of the nano-prism structure 228 is similar to the example implementation 700 of the nano-prism structure 228. The example implementation 712 of the nano-prism structure 228 includes columnar portions 714a, 714b, and 714c, which are similar to the columnar portions 702a, 702b, and 702c except that the columnar portions 714b each include a first material layer 716 and a second material layer 718, and the columnar portions 714c each include the first material layer 716, the second material layer 718, and a third material layer 720. For example, portions of the first material layer 716 are on opposite lateral sides of the columnar portions 714b, and the second material layer 718 fills in a remaining interior area of the columnar portions 714b. The first material layer 716 may be conformally deposited in a recess, and the second material layer 718 may be conformally deposited on the first material layer 716 in the recess to form the columnar portions 714b. Portions of the first material layer 716 are on opposite lateral sides of the columnar portions 714c, portions of the second material layer 718 are on interior surfaces of the portions of the first material layer 716, and the third material layer 720 fills in a remaining interior area of the columnar portions 714c. The first material layer 716 may be conformally deposited in a recess, the second material layer 718 may be conformally deposited on the first material layer 716 in the recess, and the third material layer 720 may be conformally deposited on the second material layer 718 to form the columnar portions 714c. The columnar portions 714b including two material layers (e.g., first and second material layers 716 and 718) may reduce phase velocity in comparison to, for example, columnar portions 702b and 702c including one material layer. The columnar portions 714c including three material layers (e.g., first, second, and third material layers 716, 718, and 720) may reduce phase velocity in comparison to, for example, columnar portions including one material layer, and columnar portions including two material layers.

In some implementations, the combination of materials for the material layer 230, the additional material layer 236, the columnar portions 714a, the first material layer 716, the second material layer 718, and the third material layer 720, may be any combination of nano-prism materials (e.g., a silicon oxide (e.g., SiO₂), a titanium oxide (e.g., TiO₂), a tantalum oxide (e.g., Ta₂O₅), an aluminum oxide (Al₂O₃), a hafnium oxide (e.g., HfO₂), a silicon nitride (e.g., Si₃N₄), and/or a silicon carbide (e.g., SiC)) where the refractive index of the columnar portions 714a, 714b, and 714c (e.g., n₃) is greater than the refractive index of the additional material layer 236 (e.g., n₂), which is greater than the refractive index of the material layer 230 (e.g., n₁).

As shown in FIG. 7D, the example implementation 722 of the nano-prism structure 228 is similar to the example implementation 700 of the nano-prism structure 228. The example implementation 722 of the nano-prism structure 228 includes columnar portions 724a, 724b, and 724c, which are similar to the columnar portions 702a, 702b, and 702c except that the columnar portions 724b each include a first material layer 726, a second material layer 728, and a third material layer 730, and the columnar portions 724c each include the first material layer 726, the second material layer 728, the third material layer 730, a fourth material layer 732, a fifth material layer 734, a sixth material layer 736, and seventh material layer 738. For example, portions of the first material layer 726 are on opposite lateral sides of the columnar portions 724b, portions of the second material layer 728 are on interior surfaces of the portions of the first material layer 726, and the third material layer 730 fills in a remaining interior area of the columnar portions 724b. The first material layer 726 may be conformally deposited in a recess, the second material layer 728 may be conformally deposited on the first material layer 726 in the recess, and the third material layer 730 may be conformally deposited on the second material layer 728 in the recess to form the columnar portions 724b. For each columnar portion 724c, the first-seventh material layers 726-738 are successively conformally deposited in a recess in the additional material layer 236 and the material layer 230 to form the first-seventh material layers 726-738 in a stacked arrangement in the x-direction. In some implementations, the quantity of material layers for the columnar portions 724c may be included in the range of four material layers to seven material layers. However, other values for the quantity of material layers are within the scope of this disclosure.

The columnar portions 724b including three material layers (e.g., first, second, and third material layers 726, 728 and 730) may reduce phase velocity in comparison to, for example, columnar portions including one or two material layers. The columnar portions 724c including greater than three material layers (e.g., first-seventh material layers 726-738) may reduce phase velocity in comparison to, for example, columnar portions including less than four material layers.

In some implementations, the combination of materials for the material layer 230, the additional material layer 236, the columnar portions 724a, and the first-seventh material layers 726-738, may be any combination of nano-prism materials (e.g., a silicon oxide (e.g., SiO₂), a titanium oxide (e.g., TiO₂), a tantalum oxide (e.g., Ta₂O₅), an aluminum oxide (Al₂O₃), a hafnium oxide (e.g., HfO₂), a silicon nitride (e.g., Si₃N₄), and/or a silicon carbide (e.g., SiC)) where the refractive index of the columnar portions 724a, 724b, and 724c (e.g., n₃) is greater than the refractive index of the additional material layer 236 (e.g., n₂), which is greater than the refractive index of the material layer 230 (e.g., n₁).

In the example implementation 740 in FIG. 7E, the nano-prism structure 228 of the example implementation 722 is shown in connection with two adjacent pixel sensors 104. Similar to the example implementations 200, 234, 238 and 240, the pixel sensor array 102 and pixel sensors 104 include components 202-210, 214, 222-226. The example implementation 740 further illustrates source/drain regions 742 of a transistor corresponding to the transfer gate 214. “Source/drain region” may refer to a source or a drain, individually or collectively, depending upon the context.

The example implementation 740 also schematically illustrates through dotted lines and arrows how incident light may be transmitted from the columnar portions 724a, 724b, and 724c, through the material layer 230, and through the buffer layer 222 to focal points 744 over photodiodes 204.

As indicated above, FIGS. 7A-7E are provided as an example. Other examples may differ from what is described with regard to FIGS. 7A-7E.

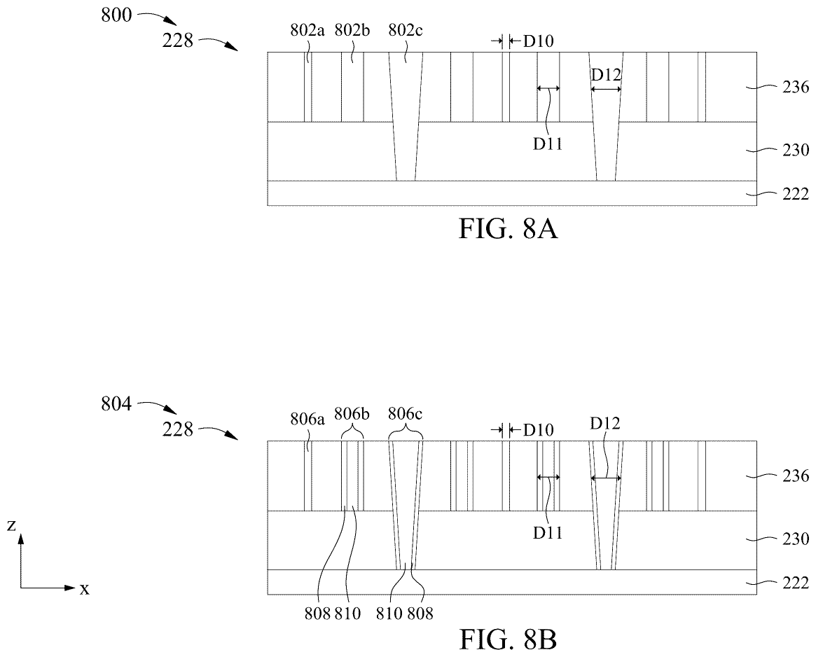

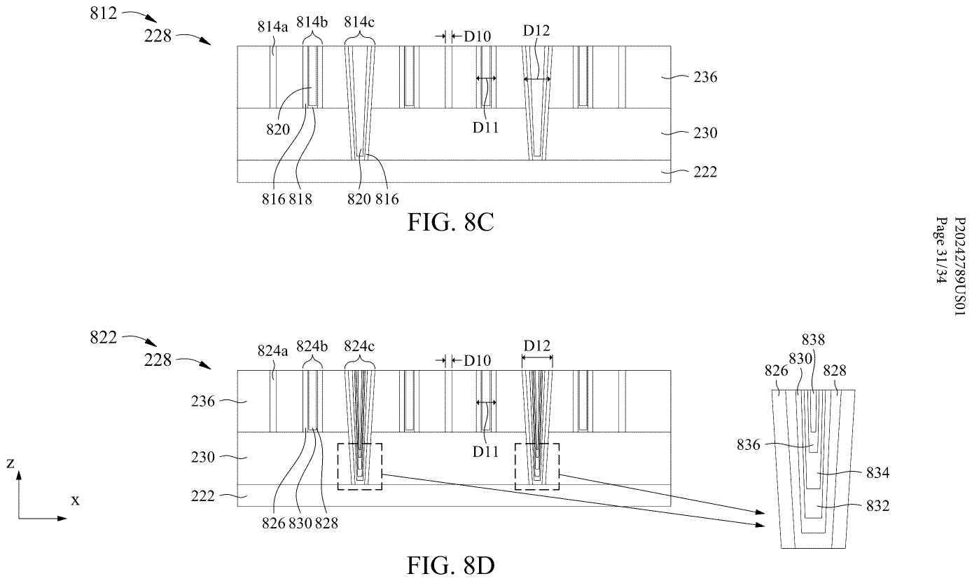

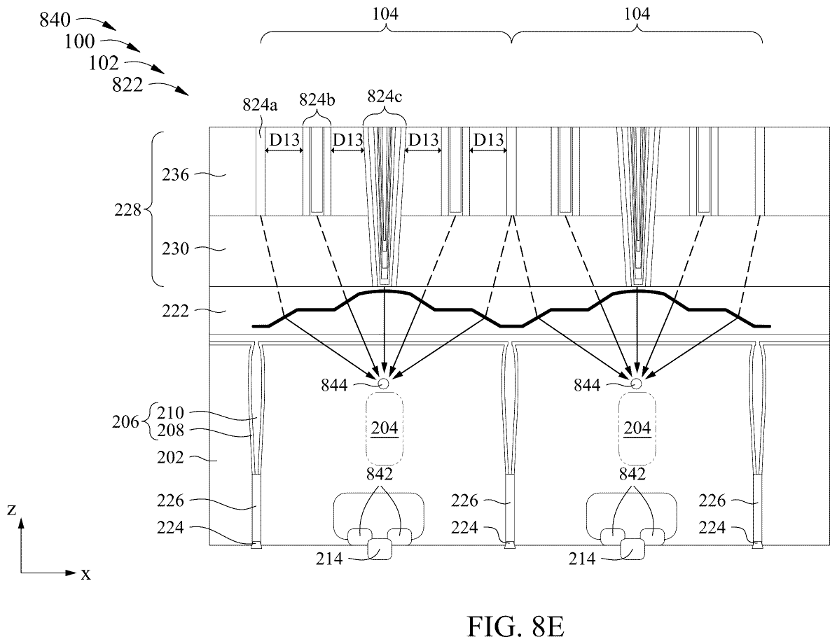

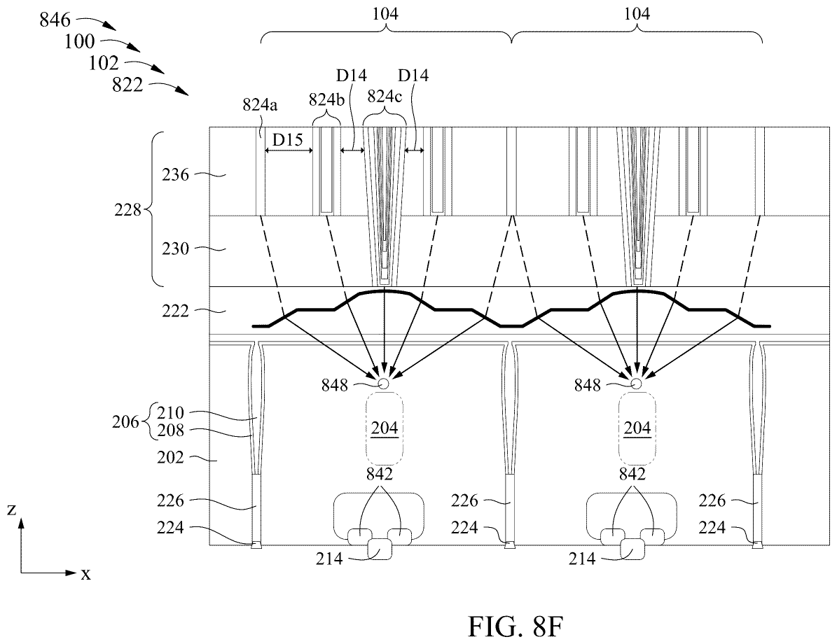

FIGS. 8A-8F are diagrams of example implementations of a portion of a pixel sensor array described herein. FIG. 8A illustrates an example implementation 800 of the nano-prism structure 228. As shown in FIG. 8A, the nano-prism structure 228 includes columnar portions in the material layer 230 and the additional material layer 236. The columnar portions 802a and 802b are only formed in the additional material layer 236, while the columnar portions 802c are formed in the material layer 230 and in the additional material layer 236. The limitations on the vertical dimension (e.g., z-direction dimension) of the columnar portions 802a and 802b in the example implementation 800 in comparison to the columnar portions formed through both of the additional material layer 236 and the material layer 230 may increase the speed of the light traveling through the columnar portions 802a and 802b and subsequently into the material layer 230, where the material layer 230 has a lower refractive index than that of the columnar portions 802a and 802b. In addition, the different vertical dimension of the columnar portions 802a and 802b from columnar portions formed through both of the additional material layer 236 and the material layer 230 may change the deflection angles of the light as well as the focal point of the light.

The columnar portions 802a, 802b, and 802c have widths (x-direction dimensions) D10, D11, and D12, respectively, where D10<D11<D12. In addition, the columnar portions 802a, 802b, and 802c are arranged in a repeating pattern (e.g., columnar portion 802a (width D10), columnar portion 802b (width D11), columnar portion 802c (width D12), columnar portion 802b (width D11)) according to respective lateral (x-direction) dimensions of the columnar portions 802a, 802b, and 802c. In some implementations, the ratio of D10:D11:D12 may be, for example, 1:2:4, 1:2:6, or 1:4:8. However, other values for the ratio of D10:D11:D12 are within the scope of the present disclosure.

In the example implementation 800, the material layer 230 includes a first material having a first refractive index n₁, the additional material layer 236 includes a second material having a second refractive index n₂, and the columnar portions 802a, 802b, and 802c each include a third material having a third refractive index n₃, where n₃>n₂>n₁. In some implementations, the material layer 230 includes a silicon oxide (e.g., SiO₂), the additional material layer 236 includes a tantalum oxide (e.g., TaO₅), which has a greater refractive index than that of a silicon oxide (e.g., SiO₂), and the columnar portions 802a, 802b, and 802c include a titanium oxide (e.g., TiO₂), which has a greater refractive index than that of a tantalum oxide (e.g., TaO₅), and of a silicon oxide (e.g., SiO₂). Other combinations of materials for the material layer 230, the additional material layer, and the columnar portions 802a, 802b, and 802c where n₃>n₂>n₁ may be used.

The combination of the rectangular shape (e.g., straight profile) of the columnar portions 802a and 802b, and the trapezoidal shape (e.g., tapered profile) of the columnar portion 802c in the example implementation 800 may result in particular deflection angles and a particular focal point of light traveling through the columnar portions 802a, 802b, and 802c, which may be different from the particular deflection angles and particular focal point of light traveling through the columnar portions 702a, 702b, and 702c in the example implementation 700.

As shown in FIG. 8B, the example implementation 804 of the nano-prism structure 228 is similar to the example implementation 800 of the nano-prism structure 228. The example implementation 804 of the nano-prism structure 228 includes columnar portions 806a, 806b, and 806c, which are similar to the columnar portions 802a, 802b, and 802c, except that the columnar portions 806b and 806c each include a first material layer 808 and a second material layer 810. For example, portions of the first material layer 808 are on opposite lateral sides of the columnar portions 806b and 806c, and the second material layer 810 fills in a remaining interior area of the columnar portions 806b and 806c. The first material layer 808 may be conformally deposited in a recess, and the second material layer 810 may be conformally deposited on the first material layer 808 in the recess to form the columnar portions 806b and 806c. The columnar portions 806b and 806c including two material layers (e.g., first and second material layers 808 and 810) may reduce phase velocity in comparison to, for example, columnar portions 802b and 802c including one material layer.

In some implementations, the combination of materials for the material layer 230, the additional material layer 236, the columnar portions 806a, the first material layer 808, and the second material layer 810, may be any combination of nano-prism materials (e.g., a silicon oxide (e.g., SiO₂), a titanium oxide (e.g., TiO₂), a tantalum oxide (e.g., Ta₂O₅), an aluminum oxide (Al₂O₃), a hafnium oxide (e.g., HfO₂), a silicon nitride (e.g., Si₃N₄), and/or a silicon carbide (e.g., SiC)) where the refractive index of the columnar portions 806a, 806b, and 806c (e.g., n₃) is greater than the refractive index of the additional material layer 236 (e.g., n₂), which is greater than the refractive index of the material layer 230 (e.g., n₁).

As shown in FIG. 8C, the example implementation 812 of the nano-prism structure 228 is similar to the example implementation 800 of the nano-prism structure 228. The example implementation 812 of the nano-prism structure 228 includes columnar portions 814a, 814b, and 814c, which are similar to the columnar portions 802a, 802b, and 802c except that the columnar portions 814b each include a first material layer 816 and a second material layer 818, and the columnar portions 814c each include the first material layer 816, the second material layer 818, and a third material layer 820. For example, portions of the first material layer 816 are on opposite lateral sides of the columnar portions 814b, and the second material layer 818 fills in a remaining interior area of the columnar portions 814b. The first material layer 816 may be conformally deposited in a recess, and the second material layer 818 may be conformally deposited on the first material layer 816 in the recess to form the columnar portions 814b. Portions of the first material layer 816 are on opposite lateral sides of the columnar portions 814c, portions of the second material layer 818 are on interior surfaces of the portions of the first material layer 816, and the third material layer 820 fills in a remaining interior area of the columnar portions 814c. The first material layer 816 may be conformally deposited in a recess, the second material layer 818 may be conformally deposited on the first material layer 816 in the recess, and the third material layer 820 may be conformally deposited on the second material layer 818 to form the columnar portions 814c. The columnar portions 814b including two material layers (e.g., first and second material layers 816 and 818) may reduce phase velocity in comparison to, for example, columnar portions 802b and 802c including one material layer. The columnar portions 814c including three material layers (e.g., first, second, and third material layers 816, 818, and 820) may reduce phase velocity in comparison to, for example, columnar portions including one material layer, and columnar portions including two material layers.

In some implementations, the combination of materials for the material layer 230, the additional material layer 236, the columnar portions 814a, the first material layer 816, the second material layer 818, and the third material layer 820, may be any combination of nano-prism materials (e.g., a silicon oxide (e.g., SiO₂), a titanium oxide (e.g., TiO₂), a tantalum oxide (e.g., Ta₂O₅), an aluminum oxide (Al₂O₃), a hafnium oxide (e.g., HfO₂), a silicon nitride (e.g., Si₃N₄), and/or a silicon carbide (e.g., SiC)) where the refractive index of the columnar portions 814a, 814b, and 814c (e.g., n₃) is greater than the refractive index of the additional material layer 236 (e.g., n₂), which is greater than the refractive index of the material layer 230 (e.g., n₁).

As shown in FIG. 8D, the example implementation 822 of the nano-prism structure 228 is similar to the example implementation 800 of the nano-prism structure 228. The example implementation 822 of the nano-prism structure 228 includes columnar portions 824a, 824b, and 824c, which are similar to the columnar portions 802a, 802b, and 802c except that the columnar portions 824b each include a first material layer 826, a second material layer 828, and a third material layer 830, and the columnar portions 824c each include the first material layer 826, the second material layer 828, the third material layer 830, a fourth material layer 832, a fifth material layer 834, a sixth material layer 836, and seventh material layer 838. For example, portions of the first material layer 826 are on opposite lateral sides of the columnar portions 824b, portions of the second material layer 828 are on interior surfaces of the portions of the first material layer 826, and the third material layer 830 fills in a remaining interior area of the columnar portions 824b. The first material layer 826 may be conformally deposited in a recess, the second material layer 828 may be conformally deposited on the first material layer 826 in the recess, and the third material layer 830 may be conformally deposited on the second material layer 828 in the recess to form the columnar portions 824b. For each columnar portion 824c, the first-seventh material layers 826-838 are successively conformally deposited in a recess in the additional material layer 236 and the material layer 230 to form the first-seventh material layers 826-838 in a stacked arrangement in the x-direction and the z-direction. For example, in some implementations, one or more of the first-seventh material layers 826-838 may be successively conformally deposited on lateral sides and on bottom surfaces of the recess in a stacked arrangement such that one or more of the first-seventh material layers 826-838 are formed in a U-shape or V-shape. The last layer of the stacked arrangement (e.g., the seventh material layer 838) fills in a remaining portion of the recess. In some implementations, the quantity of material layers for the columnar portions 824c may be included in the range of four material layers to seven material layers. However, other values for the quantity of material layers are within the scope of this disclosure.

The columnar portions 824b including three material layers (e.g., first, second, and third material layers 826, 828 and 830) may reduce phase velocity in comparison to, for example, columnar portions including one or two material layers. The columnar portions 824c including greater than three material layers (e.g., first-seventh material layers 826-838) may reduce phase velocity in comparison to, for example, columnar portions including less than four material layers.

In some implementations, the combination of materials for the material layer 230, the additional material layer 236, the columnar portions 824a, and the first-seventh material layers 826-838, may be any combination of nano-prism materials (e.g., a silicon oxide (e.g., SiO₂), a titanium oxide (e.g., TiO₂), a tantalum oxide (e.g., Ta₂O₅), an aluminum oxide (Al₂O₃), a hafnium oxide (e.g., HfO₂), a silicon nitride (e.g., Si₃N₄), and/or a silicon carbide (e.g., SiC)) where the refractive index of the columnar portions 824a, 824b, and 824c (e.g., n₃) is greater than the refractive index of the additional material layer 236 (e.g., n₂), which is greater than the refractive index of the material layer 230 (e.g., n₁).

In the example implementation 840 in FIG. 8E, the nano-prism structure 228 of the example implementation 822 is shown in connection with two adjacent pixel sensors 104. Similar to the example implementations 200, 234, 238 and 240, the pixel sensor array 102 and pixel sensors 104 include components 202-210, 214, 222-226. The example implementation 840 further illustrates source/drain regions 842 of a transistor corresponding to the transfer gate 214. “Source/drain region” may refer to a source or a drain, individually or collectively, depending upon the context.

The example implementation 840 also schematically illustrates through dotted lines and arrows how incident light may be transmitted from the columnar portions 824a, 824b, and 824c, through the material layer 230, and through the buffer layer 222 to focal points 844 over photodiodes 204. As shown in FIG. 8E, a lateral (e.g., x-direction) spacing (D13) between the columnar portions 824a and 824b, and between the columnar portions 824b and 824c is the same or approximately the same. The lateral spacing may affect the deflection angles of the light and the location of the focal points (e.g., focal points 844) of the light traveling through the columnar portions 824a, 824b, and 824c. For example, as shown in the example implementation 846 in FIG. 8F, which is similar to the example implementation 840 in FIG. 8E, the lateral (e.g., x-direction) spacing (D14) between the columnar portions 824b and 824c is decreased relative to the lateral (e.g., x-direction) spacing (D13) between the columnar portions 824b and 824c in the example implementation 840. In addition, in the example implementation 846, the lateral (e.g., x-direction) spacing (D15) between the columnar portions 824b and 824a is increased relative to the lateral (e.g., x-direction) spacing (D13) between the columnar portions 824b and 824a in the example implementation 840. As a result, the deflection angles of the light and/or the location of the focal points (e.g., focal points 848) of the light traveling through the columnar portions 824a, 824b, and 824c in the example implementation 846 may be modified relative to the deflection angles of the light and/or the location of the focal points (e.g., focal points 844) of the light traveling through the columnar portions 824a, 824b, and 824c in the example implementation 840. As shown in FIG. 8F, the lateral (e.g., x-direction) spacing (D15) between the columnar portions 824b and 824a is greater than the lateral (e.g., x-direction) spacing (D14) between the columnar portions 824b and 824c.

As indicated above, FIGS. 8A-8F are provided as an example. Other examples may differ from what is described with regard to FIGS. 8A-8F.

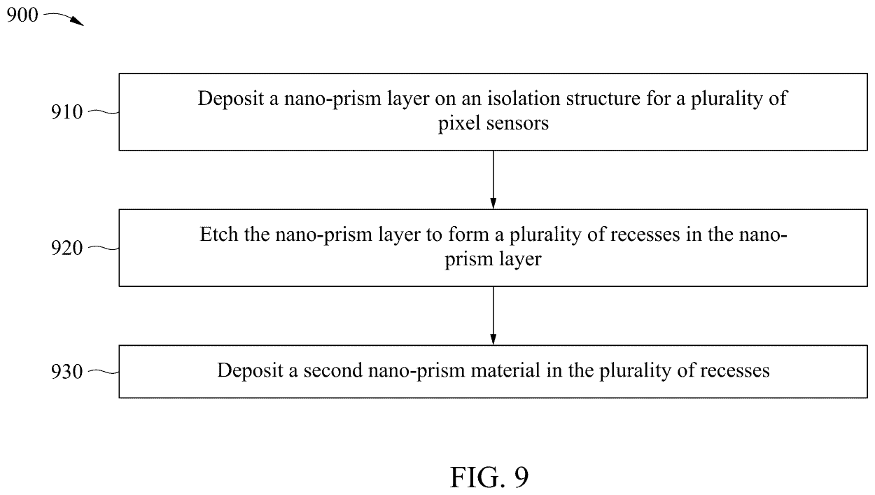

FIG. 9 is a flowchart of an example process 900 associated with a method of forming a semiconductor device. In some implementations, one or more process blocks of FIG. 9 are performed using one or more semiconductor processing tools, such as a deposition tool, an exposure tool, a developer tool, an etch tool, a planarization tool, an ion implantation tool, an annealing tool, a wafer/die transport tool, and/or another type of semiconductor processing tool.

As shown in FIG. 9, process 900 may include depositing a nano-prism layer on an isolation structure for a plurality of pixel sensors (block 910). For example, one or more semiconductor processing tools may be used to deposit a nano-prism layer (e.g., material layer 230, additional material layer 236) on an isolation structure (e.g., isolation structure 206) for a plurality of pixel sensors (e.g. pixel sensors 104), as described herein. In some implementations, the nano-prism layer includes a first nano-prism material.

As further shown in FIG. 9, process 900 may include etching the nano-prism layer to form a plurality of recesses in the nano-prism layer (block 920). For example, one or more semiconductor processing tools may be used to etch the nano-prism layer to form a plurality of recesses (e.g., recesses 304, 402, 502, 602, 604) in the nano-prism layer, as described herein. In some implementations, the plurality of recesses are spaced apart from each other in a lateral direction (e.g., x-direction).

As further shown in FIG. 9, process 900 may include depositing a second nano-prism material in the plurality of recesses (block 930). For example, one or more semiconductor processing tools may be used to deposit a second nano-prism material (e.g., material layers 708, 710, 716-720, 726-738, 808, 810, 816-820, 826-838) in the plurality of recesses, as described herein. In some implementations, a refractive index of the second nano-prism material is greater than a refractive index of the first nano-prism material.

Process 900 may include additional implementations, such as any single implementation or any combination of implementations described below and/or in connection with one or more other processes described elsewhere herein.

In a first implementation, the first nano-prism material includes a first dielectric material, and the second nano-prism material includes a second dielectric material.

In a second implementation, alone or in combination with the first implementation, a width (e.g., widths D1-D12) of each recess in a first subset of the plurality of recesses increases along the lateral direction, and a width of each recess in a second subset of the plurality of recesses adjacent to the first subset decreases along the lateral direction.

In a third implementation, alone or in combination with one or more of the first and second implementations, process 900 includes depositing a third nano-prism material (e.g., material layers 710, 718-720, 728-738, 810, 818-820, 828-838) in the plurality of recesses, where the third nano-prism material is deposited on the second nano-prism material.

Although FIG. 9 shows example blocks of process 900, in some implementations, process 900 includes additional blocks, fewer blocks, different blocks, or differently arranged blocks than those depicted in FIG. 9. Additionally, or alternatively, two or more of the blocks of process 900 may be performed in parallel.

In this way, a DVS device uses a nano-prism structure to direct and focus light toward photodiodes of pixel sensors of the DVS device. Building on some of the principles for the operation of NLPs, the nano-prism structure is arranged to control the speed and deflection angles of incident light traveling through different portions of the nano-prism structure. For example, the resulting direction and focal points of incident light may be easily modified by changing the location, dimensions, and/or materials of portions of the nano-prism structure. The nano-prism structure may be implemented without micro-lenses to focus light to non-filter (e.g., non-RGB) pixel sensors to encode per-pixel luminance changes to form digital images. As a result, DVS devices implementing the nano-prism structure may occupy less area, are more amenable to design changes, and have a lower susceptibility to light loss (and therefore higher quantum efficiency) than DVS devices using micro-lenses.

As described in greater detail above, some implementations described herein provide a device. The device includes a pixel sensor array including a plurality of pixel sensors. The device includes a nano-prism structure over the plurality of pixel sensors.

As described in greater detail above, some implementations described herein provide a method. The method includes depositing a nano-prism layer on an isolation structure for a plurality of pixel sensors, where the nano-prism layer includes a first nano-prism material. The method includes etching the nano-prism layer to form a plurality of recesses in the nano-prism layer, where the plurality of recesses are spaced apart from each other in a lateral direction. The method includes depositing a second nano-prism material in the plurality of recesses, where a refractive index of the second nano-prism material is greater than a refractive index of the first nano-prism material.

As described in greater detail above, some implementations described herein provide an image sensor device. The image sensor device includes a prism layer over a plurality of photodiodes, where the prism layer has a first refractive index. The image sensor device includes a plurality of fill portions disposed in the prism layer, where the plurality of fill portions are spaced apart from each other, and where the plurality of fill portions have at least a second refractive index different from the first refractive index.

As used herein, “satisfying a threshold” may, depending on the context, refer to a value being greater than the threshold, greater than or equal to the threshold, less than the threshold, less than or equal to the threshold, equal to the threshold, not equal to the threshold, or the like.

The terms “approximately” and “substantially” can indicate a value of a given quantity that varies within 5% of the value (e.g., ±1%, ±2%, ±3%, ±4%, ±5% of the value). These values are merely examples and are not intended to be limiting. It is to be understood that the terms “approximately” and “substantially” can refer to a percentage of the values of a given quantity in light of this disclosure.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A device, comprising:
a pixel sensor array comprising a plurality of pixel sensors; and
a nano-prism structure over the plurality of pixel sensors.

2. The device of claim 1, wherein the plurality of pixel sensors comprises non-filter pixel sensors.

3. The device of claim 1, further comprising:
a plurality of photodiodes;
an isolation structure disposed around the plurality of photodiodes; and
a dielectric layer in contact with the isolation structure,
wherein the nano-prism structure is disposed on and in contact with the dielectric layer.

4. The device of claim 1, wherein the nano-prism structure comprises:
a layer comprising a first material having a first refractive index; and
a plurality of columnar portions disposed in the layer,
wherein the plurality of columnar portions comprise a second material having a second refractive index,
wherein the plurality of columnar portions are alternately arranged with portions of the layer, and
wherein the second refractive index is greater than the first refractive index.

5. The device of claim 4, wherein a spacing between a first pair of adjacent columnar portions of the plurality of columnar portions is different from a spacing between a second pair of adjacent columnar portions of the plurality of columnar portions.

6. The device of claim 1, wherein the nano-prism structure comprises:
a first layer comprising a first material having a first refractive index; and
a second layer comprising a second material having a second refractive index,
wherein the second layer is disposed on the first layer, and
wherein the second refractive index is greater than the first refractive index.

7. The device of claim 6, wherein the nano-prism structure further comprises:
a plurality of columnar portions disposed in the first layer and in the second layer,
wherein the plurality of columnar portions comprise a third material having a third refractive index, and
wherein the third refractive index is greater than the second refractive index and is greater than the first refractive index.

8. The device of claim 7, wherein adjacent columnar portions of the plurality of columnar portions have different lateral dimensions from each other.

9. The device of claim 7, wherein the plurality of columnar portions are arranged in a repeating pattern according to respective lateral dimensions of the plurality of columnar portions.

10. The device of claim 6, wherein the nano-prism structure further comprises:
a first plurality of columnar portions disposed in the second layer; and
a second plurality of columnar portions disposed in the first layer and in the second layer,
wherein the first plurality of columnar portions and the second plurality of columnar portions comprise a third material having a third refractive index, and
wherein the third refractive index is greater than the second refractive index and is greater than the first refractive index.

11. The device of claim 6, wherein the nano-prism structure further comprises:
a plurality of columnar portions disposed in at least one of the first layer or the second layer,
wherein one or more of the plurality of columnar portions comprise a plurality of material layers, and
wherein respective material layers of the plurality of material layers comprise different materials.

12. A method, comprising:
depositing a nano-prism layer on an isolation structure for a plurality of pixel sensors,
wherein the nano-prism layer comprises a first nano-prism material;
etching the nano-prism layer to form a plurality of recesses in the nano-prism layer,
wherein the plurality of recesses are spaced apart from each other in a lateral direction; and
depositing a second nano-prism material in the plurality of recesses,
wherein a refractive index of the second nano-prism material is greater than a refractive index of the first nano-prism material.

13. The method of claim 12, wherein the first nano-prism material comprises a first dielectric material, and
wherein the second nano-prism material comprises a second dielectric material.

14. The method of claim 12, wherein a width of each recess in a first subset of the plurality of recesses increases along the lateral direction, and
wherein a width of each recess in a second subset of the plurality of recesses adjacent to the first subset decreases along the lateral direction.

15. The method of claim 14, further comprising depositing a third nano-prism material in the plurality of recesses,
wherein the third nano-prism material is deposited on the second nano-prism material.

16. An image sensor device, comprising:
a prism layer over a plurality of photodiodes,
wherein the prism layer has a first refractive index; and
a plurality of fill portions disposed in the prism layer,
wherein the plurality of fill portions are spaced apart from each other, and
wherein the plurality of fill portions have at least a second refractive index different from the first refractive index.

17. The image sensor device of claim 16, further comprising an additional prism layer on the prism layer,
wherein the additional prism layer has a third refractive index different from the first refractive index and different from the second refractive index, and
wherein the plurality of fill portions are disposed in the additional prism layer and in the prism layer.

18. The image sensor device of claim 17, further comprising a plurality of additional fill portions disposed in the additional prism layer and on the prism layer,
wherein the plurality of additional fill portions are spaced apart from each other,
wherein the plurality of additional fill portions have at least the second refractive index, and
wherein widths of the plurality of fill portions are greater than widths of the plurality of additional fill portions.

19. The image sensor device of claim 16, wherein the plurality of fill portions each comprise a plurality of layers in a stacked arrangement, and
wherein the plurality of layers comprise materials having different refractive indices from each other.

20. The image sensor device of claim 16, wherein the image sensor device is filterless.
